(19) United States
(12) Patent Application Publication
(10) Pub. No.: US 2026/0344265 A1
(43) Pub. Date: Oct. 29, 2026

(54) DISPLAY PANEL AND DISPLAY DEVICE INCLUDING THE SAME

(71) Applicant: LG DISPLAY CO., LTD., Seoul (KR)

(72) Inventor: Moonsoo Chung, Gimpo-si (KR)

(21) Appl. No.: 19/454,454

(22) Filed: Jan. 21, 2026

(30) Foreign Application Priority Data
Apr. 29, 2025 (KR) 10-2025-0056161

(51) Int. Cl. H10K 59/80; H10K 59/35

(52) U.S. Cl. CPC H10K 59/879; H10K 59/353; H10K 59/8792

(57) ABSTRACT

A display device in which the luminance difference of a curved display panel can be alleviated. The display panel has a configuration in which a first lens is disposed in a first pixel area having no curvature, a second lens is disposed in a second pixel area having a first curvature in one side of the first pixel area, a third lens is disposed in a third pixel area having a second curvature in another side of the first pixel area, and the second lens and the third lens are disposed so as to partially overlap with each pixel.

### CROSS REFERENCE TO RELATED APPLICATION

This application claims priority from and the benefit of Korean Patent Application No. 10-2025-0056161, filed on Apr. 29, 2025, which is hereby incorporated by reference for all purposes as if fully set forth herein.

### BACKGROUND

### FIELD

Embodiments of the invention relate generally to a display device in which the luminance difference of a curved display panel may be alleviated.

### DISCUSSION OF THE BACKGROUND

A curved display device may include a plastic organic light-emitting diode (POLED) to reproduce an input image on a curved display panel. The curved display device may provide users with images having enhanced three-dimensional effect, immersion, and presence through a curved display area.

The curved display device may be bent in the front surface direction (inner curved), and may also be bent in the rear surface direction (outer curved).

However, in a case where the curved display device is bent, a higher curvature acts on both side ends of the display panel than the center thereof. This curvature causes the both side ends of the display panel to have a luminance less than that of the central portion, which problematically increases the difference in viewing angle for the viewer.

The above information disclosed in this Background section is only for understanding of the background of the inventive concepts, and, therefore, it may contain information that does not constitute prior art.

### SUMMARY

A display panel and a display device including the same, according to embodiments of the invention, are capable of improving luminance uniformity by adding an organic light-emitting device to each sub-pixel and changing the position of a lens corresponding thereto, in order to solve the above-mentioned problem in a curved display device.

Additional features of the inventive concepts will be set forth in the description which follows, and in part will be apparent from the description, or may be learned by practice of the inventive concepts.

According to one or more embodiments of the invention, a display panel includes: a first pixel area; a second pixel area disposed on a first side of the first pixel area; a third pixel area disposed on a second side of the first pixel area and facing the second pixel area with the first pixel area interposed therebetween; a plurality of first sub-pixels disposed in the first pixel area; a plurality of second sub-pixels disposed in the second pixel area; a plurality of third sub-pixels disposed in the third pixel area; a plurality of first lenses disposed to correspond to the plurality of first sub-pixels, respectively; a plurality of second lenses disposed to correspond to the plurality of second sub-pixels, respectively; and a plurality of third lenses disposed to correspond to the plurality of third sub-pixels, respectively. The second pixel area is curved toward a rear surface of the display panel and has a first curvature; the third pixel area is curved toward a rear surface of the display panel and has a second curvature; the plurality of first sub-pixels overlap the plurality of first lenses, respectively; and the plurality of second lenses and third lenses partially overlap with the plurality of second sub-pixels and third sub-pixels, respectively.

One of the plurality of second sub-pixels entirely may overlap with the second lens as a whole, and another one of the plurality of second sub-pixels may only partially overlap with the second lens. One of the plurality of third sub-pixels may overlap with the third lens as a whole, and another one of the plurality of second sub-pixels may only partially overlap with the third lens.

In the first pixel area, the plurality of first sub-pixels may overlap with the plurality of first lenses, respectively, so that each of the plurality of first sub-pixels is entirely covered by each of the plurality of first lenses. In the second pixel area, one of the plurality of second sub-pixels may overlap with one second lens so as to be entirely covered by the one second lens, and another one of the plurality of second sub-pixels may partially overlap with another second lens so as to be partially covered by the another second lens. In the third pixel area, one of the plurality of third sub-pixels may overlap with one third lens so as to be entirely covered by the one third lens, and another one of the plurality of third sub-pixels may partially overlap with another third lens so as to be partially covered by the another third lens.

The plurality of second sub-pixels may include a second-first sub-pixel disposed toward a one-side outer peripheral portion and a second-second sub-pixel disposed toward the first pixel area. The plurality of third sub-pixels may include a third-first sub-pixel disposed toward another-side outer peripheral portion and a third-second sub-pixel disposed toward the first pixel area. The plurality of second lenses may include a second-first lens overlapping with the second-first sub-pixel and a second-second lens partially overlapping with the second-second sub-pixel. The plurality of third lenses may include a third-first lens overlapping with the third-first sub-pixel and a third-second lens partially overlapping with the third-second sub-pixel.

The second-second lens may be disposed to be shifted by a certain distance in a direction from the second-second sub-pixel to the first pixel area. The third-second lens may be disposed to be shifted by a certain distance in a direction from the third-second sub-pixel to the first area.

Each of the plurality of first sub-pixels, second sub-pixels, and third sub-pixels may have a same size, area, and thickness.

Each of the plurality of first lenses, second lenses, and third lenses may have a same shape, diameter, thickness, and length.

Each of the plurality of first lenses, second lenses, and third lenses may have a same shape, and may have different diameters, thicknesses, and lengths from each other.

The first pixel area may be in a flat state without being curved or bent in a front surface direction that is a direction in which light is emitted from each sub-pixel. The second pixel area may be curved toward the rear surface with the first curvature. The third pixel area may be curved in the rear surface direction with the second curvature to be symmetrical to the second pixel area in a transverse direction with respect to the first pixel area.

A value of the first curvature and a value of the second curvature may be substantially the same. According to another embodiment, a value of the first curvature and a value of the second curvature may be different from each other.

The first pixel area may be disposed at a center of the display panel. The second pixel area may be disposed on a first side of the first pixel area. The third pixel area may be disposed on a second side of the first pixel area so as to face the second pixel area, with the first pixel area interposed therebetween.

In a case where the second lens and the third lens are of a half-spherical type, each of the diameter, thickness, and length of the second-second lens may be greater than each of the diameter, thickness, and length of the second-first lens, respectively, and each of the diameter, thickness, and length of the third-second lens is greater than each of the diameter, thickness, and length of the third-first lens, respectively.

The first pixel area, the second pixel area, and the third pixel area may include: a first insulating layer, the plurality of first, second, and third sub-pixels being disposed on the first insulating layer; a second insulating layer disposed on the plurality of first, second, and third sub-pixels; a black matrix partially opened on the second insulating layer; and a third insulating layer disposed on the black matrix, the plurality of first, second, and third lenses being disposed on the third insulating layer. The black matrix may include a plurality of first openings opened to respectively correspond to the plurality of first sub-pixels, a plurality of second openings opened to respectively correspond to the plurality of second sub-pixels, and a plurality of third openings opened to respectively correspond to the plurality of third sub-pixels. In the second pixel area, one of the plurality of second sub-pixels may overlap with one of the plurality of second openings, and another one of the plurality of second sub-pixels may partially overlap with the other of the plurality of second openings. In the third pixel area, one of the plurality of third sub-pixels may overlap with one of the plurality of third openings, and another one of the plurality of third sub-pixels may partially overlap with another one of the plurality of third openings.

According to yet another embodiment of the invention, a display device includes the display panel of the embodiment described above, and further includes: a data driver configured to apply a data voltage to the display panel; a gamma driver configured to apply a gamma voltage to the display panel; a gate driver configured to apply a gate voltage to the display panel; and a controller configured to control the data driver and the gate driver. The plurality of first sub-pixels overlap the plurality of first lenses, respectively. One of the plurality of second pixels entirely overlaps with one of the second lenses, and another one of the plurality of second pixels partially overlaps with the other of the second lenses. One of the plurality of third pixels entirely overlaps with one of the third lenses, and another one of the plurality of third pixels partially overlaps with the other of the third lenses. The gamma driver applies, to the second pixel area, a second gamma voltage lower than a first gamma voltage applied to the first pixel area, and applies, to the third pixel area, a third gamma voltage lower than the first gamma voltage.

The gamma driver may apply, to each of the first pixel area, the second pixel area, and the third pixel area, a gamma reference high voltage having a same voltage level. The gamma driver may apply, to the second pixel area and the third pixel area, second and third gamma reference low voltages lower than a first gamma reference low voltage applied to the first pixel area, respectively.

The gate driver may include a scan driver configured to apply a scan signal to the display panel, and a light-emitting driver configured to apply an emission signal to the display panel. The light-emitting driver may apply, to the second pixel area, a second emission signal with a pulse width less than a pulse width of a first emission signal applied to the first pixel area, and may apply, to the third pixel area, a third emission signal with a pulse width less than the pulse width of the first emission signal.

The data driver may apply an offset to data voltage applied to each of the second pixel area and the third pixel area to apply a data voltage higher than that of the first pixel area by 10 gray voltage.

An odd number line and an even number line extending in a vertical direction may be disposed in each of the first pixel area, the second pixel area, and the third pixel area. One of the plurality of first sub-pixels may be connected to the odd number line or the even number line, and another one of the plurality of first sub-pixels may be connected to the even number line or the odd number line, respectively. One of the plurality of second sub-pixels may be connected to the odd number line or the even number line, and another one of the plurality of second sub-pixels may be connected to the even number line or the odd number line, respectively. One of the plurality of third sub-pixels may be connected to the odd number line or the even number line, and another one of the plurality of third sub-pixels may be connected to the even number line or the odd number line, respectively.

According to still another embodiment of the invention, a display panel includes a first pixel area, a second pixel area disposed on a first side of the first pixel area, a third pixel area disposed on a second side of the first pixel area, a plurality of first sub-pixels disposed in the first pixel area, a plurality of second sub-pixels disposed in the second pixel area, a plurality of third sub-pixels disposed in the third pixel area, a plurality of first lenses disposed to correspond to the plurality of first sub-pixels, respectively, a plurality of second lenses disposed to correspond to the plurality of second sub-pixels, respectively, and a plurality of third lenses disposed to correspond to the plurality of third sub-pixels, respectively, in which the second pixel area is bendable toward a rear surface of the display panel, the third pixel area is bendable toward the rear surface of the display panel, and when viewed in plan, at least one of the plurality of second sub-pixels is partially exposed from a corresponding one of the plurality of second lenses, while the remaining second sub-pixels are entirely covered by their corresponding second lenses

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a perspective view schematically illustrating an external appearance shape of a display panel according to an embodiment of the invention.

FIG. 2 is a diagram illustrating an example in which sub-pixels and lenses are disposed in first to third regions of a display panel according to an embodiment of the invention.

FIG. 3 is a diagram illustrating an arrangement example of respective lenses in the first pixel area and the second pixel area.

FIG. 4 is a diagram illustrating an arrangement example of respective lenses in the first pixel area and the third pixel area.

FIG. 5 is a diagram illustrating luminance distribution of a first sub-pixel through a first lens.

FIG. 6A and FIG. 6B are diagrams illustrating luminance distribution of a second sub-pixel through a second lens.

FIG. 7 is a cross-sectional view of a first pixel area taken along line I-I” of FIG. 2.

FIG. 8 is a cross-sectional view of a second pixel area taken along line II-II” of FIG. 2.

FIG. 9 is a cross-sectional view of a third pixel area taken along line III-III” of FIG. 2.

FIG. 10 is a diagram illustrating an equivalent circuit diagram for a pixel circuit of each sub-pixel.

FIG. 11 is a block diagram schematically illustrating a display device of an embodiment of the invention.

FIG. 12 is a diagram schematically illustrating the wiring structure of a display panel.

FIGS. 13A, 13B and 13C are diagrams illustrating gamma voltages, pulse widths, and offset voltages compensating for luminance differences of respective R, G, and B pixels.

FIG. 14 is a diagram illustrating an example in which odd number and even number lines are disposed on a display panel.

FIG. 15 is a diagram illustrating an example in which a sub-pixel is connected to an odd number line.

FIG. 16 is a diagram illustrating an example in which a sub-pixel is connected to an even number line.

FIGS. 17A and 17B are perspective views illustrating a shape structure of each lens.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

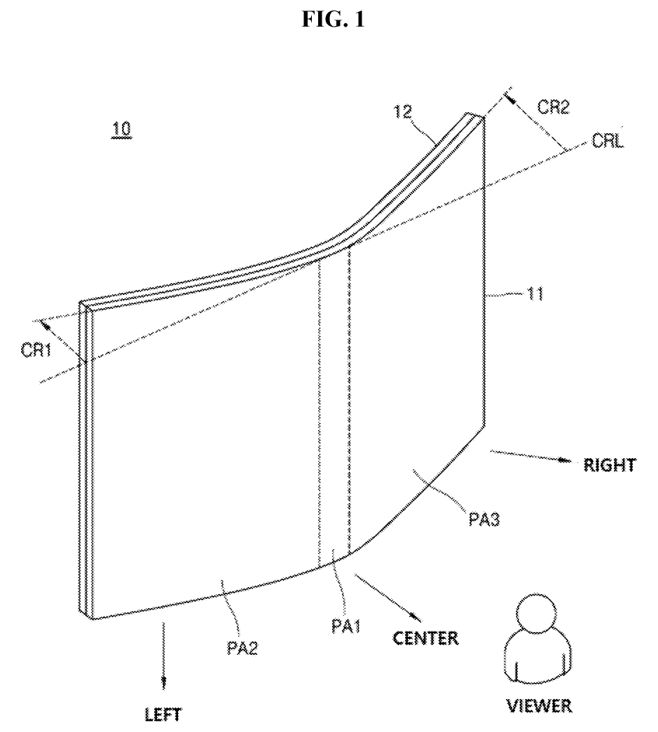

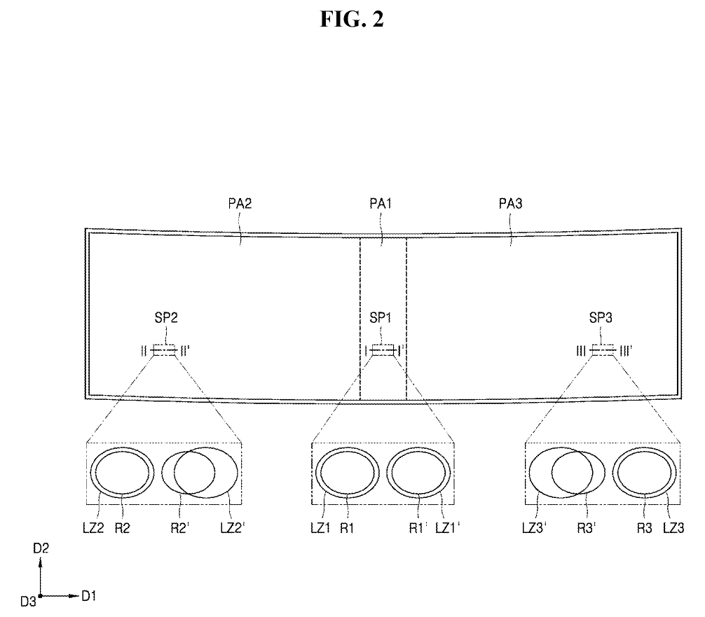

FIG. 1 is a perspective view schematically illustrating an external appearance shape of a display panel according to an embodiment of the invention. FIG. 2 is a diagram illustrating an example in which sub-pixels and lenses are disposed in first to third regions of a display panel according to an embodiment of the invention.

Referring to FIG. 1, a display panel 10 according to an embodiment of the invention may include a first substrate 11 and a second substrate 12.

When viewed from a viewer’s perspective, the first substrate 11 may be disposed on a front side, and the second substrate 12 may be disposed on a rear side.

In a case where the display panel 10 is laid down in a left or right direction, the first substrate 11 may be disposed on the top side, and the second substrate 12 may be disposed on the bottom side, or the first substrate 11 may be disposed on the bottom side and the second substrate 12 may be disposed on the top side.

The first substrate 11 may include an upper glass, and the second substrate 12 may include a bottom glass.

The first substrate 11 and the second substrate 12 may be formed of, for example, a flexible material selected from a group of consisting of poly ethylene naphthalate (PEN), poly ethylene terephthalate (PET), poly ethylene ether phthalate, poly carbonate (PC), polyarylate, polyether imide, polyether sulfonate, polyimide, or polyacrylate.

The first substrate 11 may include a plurality of pixel areas. The second substrate 12 may include a plurality of TFT areas. The plurality of TFT areas may be disposed at positions corresponding to the plurality of pixel regions.

The first substrate 11 may be correspondingly bonded to the second substrate 12, for example, by an adhesive. The first substrate 11 and the second substrate 12 may each be bent in the rearward direction. When bent in the rearward direction, a compressive stress acts on the second substrate 12 disposed on the rear side, and a tensile stress acts on the first substrate 11 disposed on the front side. When the first substrate 11 is bent in the rearward direction together with the second substrate 12, it is subjected to the tensile stress.

Although not shown, the first substrate 11 may include an active area for displaying an image.

The display panel 10 may include a first pixel area PA1, a second pixel area PA2, and a third pixel area PA3.

The first pixel area PA1 may be disposed at a center when viewed from a viewer’s perspective. The second pixel area PA2 may be disposed on one side or the left side of the first pixel area PA1, and the third pixel area PA3 may be disposed on the other side or the right side of the first pixel area PA1, and may be disposed at a position facing the second pixel area PA2 with respect to the first pixel area PA1. For example, when viewed from a viewer’s perspective, the second pixel area PA2 may be located on the left side, and the third pixel area PA3 may be located on the right side.

The first pixel area PA1 may be in a flat state without being curved or bent in the front surface direction that is a direction in which light is emitted from each sub-pixel. For example, the first pixel area PA1 is not subjected to curvature, so that it may be in a flat state without being curved.

The second pixel area PA2 may be curved in the rear surface direction with a first curvature CR1, and the third pixel area PA3 may be curved in the rear surface direction with a second curvature CR2 to be symmetrical to the second pixel area PA2 in a transverse direction with respect to the first pixel area PA1.

For example, the second pixel area PA2 may be curved in the rear surface direction with a first curvature CR1 from a curvature reference line CRL, and the third pixel area PA3 may be curved in the rear surface direction with a second curvature CR2 from the curvature reference line CRL. According to an embodiment, the second pixel area PA2 and the third pixel area PA3 may be bendable.

The first curvature CR1 and the second curvature CR2 may have the same value. However, the inventive concepts are not limited to this, and, for example, the first curvature CR1 and the second curvature CR2 may have different values.

Referring to FIG. 2, the first pixel area PA1 may include a first sub-pixel area SP1, the second pixel area PA2 may include a second sub-pixel area SP2, and the third pixel area PA3 may include a third sub-pixel area SP3.

In the first sub-pixel area SP1, a plurality of first sub-pixels R1, R1’ may be disposed. In the second sub-pixel area SP2, a plurality of second sub-pixels R2, R2’ may be disposed. In the third sub-pixel area SP3, a plurality of third sub-pixels R3, R3’ may be disposed. The plurality of first sub-pixels R1, R1’, the plurality of second sub-pixels R2, R2’, and the plurality of third sub-pixels R3, R3’ may each emit, for example, one of red light, green light, and blue light.

A plurality of first lenses LZ1, LZ1’ may be disposed to correspond to the plurality of first sub-pixels R1, R1’, respectively. For example, the plurality of first lenses LZ1, LZ1’ may be disposed on the plurality of first sub-pixels R1, R1’, respectively. The plurality of first sub-pixels R1, R1’ may be disposed to overlap with the plurality of first lenses LZ1, LZ1’, respectively.

A plurality of second lenses LZ2, LZ2’ may be disposed to correspond to the plurality of second sub-pixels R2, R2’, respectively. For example, the plurality of second lenses LZ2, LZ2’ may be disposed on the plurality of second sub-pixels R2, R2’ to respectively overlap with them.

A plurality of third lenses LZ3, LZ3’ may be disposed to correspond to the plurality of third sub-pixels R3, R3’, respectively. For example, the plurality of third lenses LZ3, LZ3’ may be disposed on the plurality of third sub-pixels R3, R3’ to respectively overlap with them.

The plurality of first sub-pixels R1, R1’ may include a first-first sub-pixel R1 and a first-second sub-pixel R1’. The plurality of first lenses LZ1, LZ1’ respectively corresponding to them may include a first-first lens LZ1 and a first-second lens LZ1’.

The plurality of second sub-pixels R2, R2’ may include a second-first sub-pixel R2 and a second-second sub-pixel R2’. The plurality of second lenses LZ2, LZ2’ respectively corresponding to them may include a second-first lens LZ2 and a second-second lens LZ2’.

The plurality of third sub-pixels R3, R3’ may include a third-first sub-pixel R3 and a third-second sub-pixel R3’. The plurality of third lenses LZ3, LZ3’ respectively corresponding to them may include a third-first lens LZ3 and a third-second lens LZ3’.

The plurality of first lenses LZ1, LZ1’ may be disposed on the plurality of first sub-pixels R1, R1’, respectively, so as to overlap with the plurality of first sub-pixels R1, R1’, respectively.

Unlike the plurality of first lenses LZ1, LZ1’, the plurality of second lenses LZ2, LZ2’ and third lenses LZ3, LZ3’ may be disposed to partially overlap with the plurality of second sub-pixels R2, R2’ and third sub-pixels R3, R3’, respectively.

One R2 of the plurality of second sub-pixels R2, R2’ may overlap with the second lens LZ2 as a whole, and the other R2’ may only partially overlap with the second lens LZ2'. For example, one R2 of the plurality of second sub-pixels R2, R2’ may overlap with the second-first lens LZ2 as a whole so that it is entirely covered by the second-first lens LZ2, while the second-second sub-pixel R2’ may only partially overlap with the second-second lens LZ2’ so that it is not entirely covered or be partially exposed from the second-second lens LZ2’ when viewed in plan.

One R3 of the plurality of third sub-pixels R3, R3’ may overlap with the third lens LZ3 as a whole, and the other R3’ may only partially overlap with the third lens LZ3'. For example, one R3 of the plurality of third sub-pixels R3, R3’ may overlap with the third-first lens LZ3 as a whole so that it is entirely covered by the third-first lens LZ3, while the third-second sub-pixel R3’ may only partially overlap with the third-second lens LZ3’ so that it is not entirely covered or be partially exposed from the third-second lens LZ3’ when viewed in plan.

In the first pixel area PA1, the plurality of first sub-pixels R1, R1’ may overlap with the plurality of first lenses LZ1, LZ1’, respectively so that each of them is entirely covered by each of the plurality of the first lenses LZ1, LZ1'.

For example, in a case where the first-first sub-pixel R1 has a circular shape, the entire circular shape of the first-first sub-pixel R1 may overlap with the first-first lens LZ1 so that the entire circular shape is covered by the first-first lens LZ1. In this regard, when the first-first lens LZ1 has a circular shape, the diameter of the first-first lens LZ1 may be greater than the diameter of the first-first sub-pixel R1.

Additionally, in a case where the first-second sub-pixel R1' also has a circular shape, the entire circular shape of the first-second sub-pixel R1' may overlap with the first-second lens LZ1' so that the entire circular shape is covered by the first-second lens LZ1'. In this regard, when the first-second lens LZ1' has a circular shape, the diameter of the first-second lens LZ1' may be greater than the diameter of the first-second sub-pixel R1'.

In the second pixel area PA2, one R2 of the plurality of second sub-pixels R2, R2’ may overlap with one second lens LZ2 so that it is entirely covered by the second lens LZ2, while the other R2’ may partially overlap with the other second lens LZ2’ so that it is partially covered by the second lens LZ2'.

For example, in a case where the second-first sub-pixel R2 has a circular shape, the entire circular shape of the second-first sub-pixel R2 may overlap with the second-first lens LZ2 so that the entire circular shape is covered by the second-first lens LZ2. In this regard, when the second-first lens LZ2 has a circular shape, the diameter of the second-first lens LZ2 may be greater than the diameter of the second-first sub-pixel R2.

Additionally, in a case where the second-second sub-pixel R2’ also has a circular shape, the entire circular shape may not be entirely covered by the second-second lens LZ2', and, for example, about six-sevenths of the circular shape of the second-second sub-pixel R2’ may overlap with the second-second lens LZ2'. In this regard, when the second-second lens LZ2' has a circular shape, the diameter of the second-second lens LZ2' may be greater than the diameter of the second-second sub-pixel R2'.

In the third pixel area PA3, one R3 of the plurality of third sub-pixels R3, R3’ may overlap with the single third lens LZ3 as a whole so that it is entirely covered by the third lens LZ3, while the other R3’ may partially overlap with the other third lens LZ3’ so that it is partially covered by the third lens LZ3'.

For example, in a case where the third-first sub-pixel R3 has a circular shape, the entire circular shape of the third-first sub-pixel R3 may overlap with the third-first lens LZ3 so that the entire circular shape is covered by the third-first lens LZ3. In this regard, when the third-first lens LZ3 has a circular shape, the diameter of the third-first lens LZ3 may be greater than the diameter of the third-first sub-pixel R3.

Additionally, in a case where the third-second sub-pixel R3’ also has a circular shape, the entire circular shape may not be entirely covered by the third-second lens LZ3', and, for example, about six-sevenths of the circular shape of the third-second sub-pixel R3’ may overlap with the third-second lens LZ3'. In this regard, when the third-second lens LZ3' has a circular shape, the diameter of the third-second lens LZ3' may be greater than the diameter of the third-second sub-pixel R3'.

Although in the above-described embodiments, the plurality of first sub-pixels R1, R1’, the plurality of second sub-pixels R2, R2’, the plurality of third sub-pixels R3, R3’, the plurality of first lenses LZ1, LZ1’, the plurality of second lenses LZ2, LZ2’, and the plurality of third lenses LZ3, LZ3’ were described as having a circular shape, the inventive concepts are not limited to this, and, for example, may be implemented in various shapes, including elliptical, triangular, rectangular, pentagonal, or other polygonal shapes.

The plurality of second sub-pixels R2, R2’ may include a second-first sub-pixel R2 disposed toward a one-side outer peripheral portion of the second pixel area PA2 and a second-second sub-pixel R2’ disposed toward the first pixel area PA1.

The plurality of third sub-pixels R3, R3’ may include a third-first sub-pixel R3 disposed toward the other-side outer peripheral portion of the third pixel area PA3 and a third-second sub-pixel R3’ disposed toward the first pixel area PA1 in the third pixel area PA3.

The plurality of second lenses LZ2, LZ2’ may include a second-first lens LZ2 overlapping with the second-first sub-pixel R2 and a second-second lens LZ2’ partially overlapping with the second-second sub-pixel R2'.

The plurality of third lenses LZ3, LZ3’ may include a third-first lens LZ3 overlapping with the third-first sub-pixel R3 and a third-second lens LZ3’ partially overlapping with the third-second sub-pixel R3'.

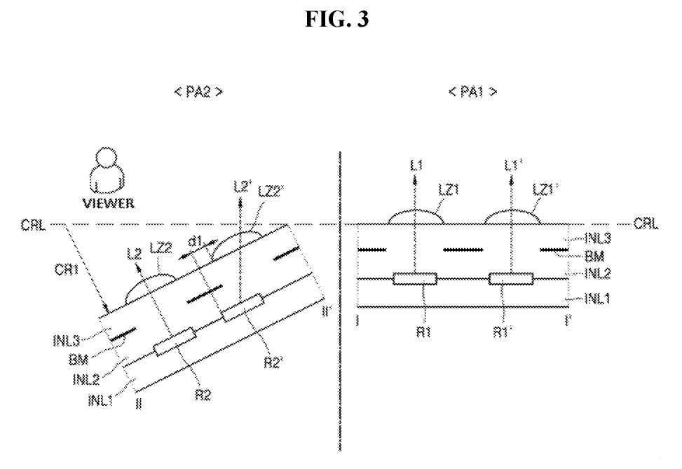

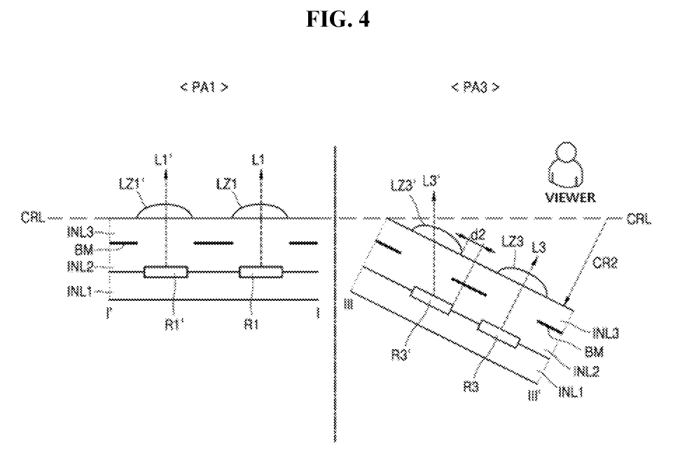

FIG. 3 is a diagram illustrating an example of the arrangement of respective lenses corresponding to respective sub-pixels in the first area and the second area according to an embodiment of the invention, and FIG. 4 is a diagram illustrating an example of the arrangement of respective lenses corresponding to respective sub-pixels in the first area and the third area according to an embodiment of the invention.

Referring to FIGS. 3 and 4, the first pixel area PA1 is a flat area with no curvature applied, includes the first-first sub-pixel R1 and the first-second sub-pixel R1', and also includes the first-first lens LZ1 and the first-second lens LZ1', which are correspondingly disposed to overlap with the sub-pixels, respectively.

For example, in the first pixel area PA1 according to an embodiment of the invention, the first-first sub-pixel R1 and the first-second sub-pixel R1’ may be disposed on a first insulating layer INL1 to be spaced apart from each other; a second insulating layer INL2 may be disposed on the first-first sub-pixels R1 and first-second sub-pixels R1’; a partially opened black matrix BM may be disposed on the second insulating layer INL2; a third insulating layer INL3 may be disposed on the black matrix BM; and the first-first lens LZ1 and the first-second lens LZ1’ may be disposed on the third insulating layer INL3 to be spaced apart from each other.

The first-first lens LZ1 may be disposed on the third insulating layer INL3 to correspond to the first-first sub-pixel R1 and to overlap vertically with the first-first sub-pixel R1.

The first-second lens LZ1' may be disposed on the third insulating layer INL3 to correspond to the first-second sub-pixel R1' and to overlap vertically with the first-second sub-pixel R1'.

The black matrix BM may be opened at a position where the first-first lens LZ1 and the first-first sub-pixel R1 overlap vertically with each other, and may be opened at a position where the first-second lens LZ1’ and the first-second sub-pixel R1’ overlap vertically with each other.

First-first light L1 emitted from the first-first sub-pixel R1 may pass through the central portion of the first-first lens LZ1 and be output, and first-second light L1’ emitted from the first-second sub-pixel R1’ may pass through the central portion of the first-second lens LZ1’ and be output.

Referring to FIG. 3, the second pixel area PA2 is a region curved in the rear surface direction with the first curvature CR1 from the curvature reference line CRL when viewed by the viewer, includes the second-first sub-pixel R2 and the second-second sub-pixel R2', and also includes the second-first lens LZ2 and the second-second lens LZ2', which are correspondingly disposed to overlap with the sub-pixels, respectively.

For example, in the second pixel area PA2 according to an embodiment of the invention, the second-first sub-pixel R2 and the second-second sub-pixel R2’ may be disposed on a first insulating layer INL1 to be spaced apart from each other; a second insulating layer INL2 may be disposed on the second-first sub-pixels R2 and second-second sub-pixels R2’; a partially opened black matrix BM may be disposed on the second insulating layer INL2; a third insulating layer INL3 may be disposed on the black matrix BM; and the second-first lens LZ2 and the second-second lens LZ2’ may be disposed on the third insulating layer INL3 to be spaced apart from each other.

The second-first lens LZ2 may be disposed on the third insulating layer INL3 to correspond to the second-first sub-pixel R2 and to overlap vertically with the second-first sub-pixel R2.

The second-second lens LZ2' may be disposed on the third insulating layer INL3 to correspond to the second-second sub-pixel R2' and to overlap partially and vertically with the second-second sub-pixel R2'. The second-second lens LZ2’ may be disposed to be shifted by a certain distance, for example, a first distance d1, in the direction from the second-second sub-pixel R2’ to the first pixel area PA1.

The black matrix BM may be opened at a position where the second-first lens LZ2 and the second-first sub-pixel R2 overlap vertically with each other, and may be opened at a position where the second-second lens LZ2’ and the second-second sub-pixel R2’ overlap partially and vertically with each other.

Second-first light L2 emitted from the second-first sub-pixel R2 may pass through the central portion of the second-first lens LZ2 and be output, and second-second light L2′ emitted from the second-second sub-pixel R2′ may pass through the second-second lens LZ2′ at a slightly deviated angle toward the first pixel area PA1 from the central portion of the second-second lens LZ2′ and be output.

Referring to FIG. 4, the third pixel area PA3 is a region curved in the rear surface direction with the second curvature CR2 from the curvature reference line CRL when viewed by the viewer, includes the third-first sub-pixel R3 and the third-second sub-pixel R3', and also includes the third-first lens LZ3 and the third-second lens LZ3', which are correspondingly disposed to overlap with the sub-pixels, respectively.

For example, in the third pixel area PA3 according to an embodiment of the invention, the third-first sub-pixel R3 and the third-second sub-pixel R3’ may be disposed on a first insulating layer INL1 to be spaced apart from each other; a second insulating layer INL2 may be disposed on the third-first sub-pixels R3 and third-second sub-pixels R3’; a partially opened black matrix BM may be disposed on the second insulating layer INL2; a third insulating layer INL3 may be disposed on the black matrix BM; and the third-first lens LZ3 and the third-second lens LZ3’ may be disposed on the third insulating layer INL3 to be spaced apart from each other.

The third-first lens LZ3 may be disposed on the third insulating layer INL3 to correspond to the third-first sub-pixel R3 and to overlap vertically with the third-first sub-pixel R3.

The third-second lens LZ3' may be disposed on the third insulating layer INL3 to correspond to the third-second sub-pixel R3' and to overlap partially and vertically with the third-second sub-pixel R3'. The third-second lens LZ3’ may be disposed to be shifted by a certain distance, for example, a second distance d2, in the direction from the third-second sub-pixel R3’ to the first pixel area PA1.

The black matrix BM may be opened at a position where the third-first lens LZ3 and the third-first sub-pixel R3 overlap vertically with each other, and may be opened at a position where the third-second lens LZ3’ and the third-second sub-pixel R3’ overlap partially and vertically with each other.

Third-first light L3 emitted from the third-first sub-pixel R3 may pass through the central portion of the third-first lens LZ3 and be output, and third-second light L3′ emitted from the third-second sub-pixel R3′ may pass through the third-second lens LZ3′ at a slightly deviated angle toward the first pixel area PA1 from the central portion of the third-second lens LZ3′ and be output.

A plurality of first sub-pixels R1, R1′, second sub-pixels R2, R2′, and third sub-pixels R3, R3′ may each have the same size, area, and thickness. However, embodiments of the invention are not limited to this. A plurality of first sub-pixels R1, R1′, second sub-pixels R2, R2′, and third sub-pixels R3, R3′ may each have different sizes, areas, and thicknesses from each other.

A plurality of first lenses LZ1, LZ1′, second lenses LZ2, LZ2′, and third lenses LZ3, LZ3′ may each have the same shape, diameter, thickness, and length. However, embodiments of the invention are not limited to this. A plurality of first lenses LZ1, LZ1′, second lenses LZ2, LZ2′, and third lenses LZ3, LZ3′ may each have different shapes, diameters, thicknesses, and lengths from each other. Additionally, a plurality of first lenses LZ1, LZ1′, second lenses LZ2, LZ2′, and third lenses LZ3, LZ3′ may each have the same shape and have different diameters, thicknesses, and lengths from each other.

When the second lenses LZ2, LZ2′ are of a half-spherical type, the diameter, thickness, and length of the second-second lens LZ2′ may each have a greater value than those of the second-first lens LZ2.

When the third lenses LZ3, LZ3′ are of a half-spherical type, the diameter, thickness, and length of the third-first lens LZ3 may each have a greater value than those of the third-second lens LZ3′.

Referring to FIGS. 3 and 4, the first pixel area PA1, the second pixel area PA2, and the third pixel area PA3 according to an embodiment of the invention may include the first insulating layer INL1; the plurality of first sub-pixels R1, R1′, second sub-pixels R2, R2′, and third sub-pixels R3, R3′ on the first insulating layer; the second insulating layer INL2 on the plurality of first, second, and third sub-pixels; the black matrix BM partially opened on the second insulating layer; the third insulating layer INL3 on the black matrix; and the plurality of first lenses LZ1, LZ1′, second lenses LZ2, LZ2′, and third lenses LZ3, LZ3′ on the third insulating layer.

The black matrix BM may include a plurality of first openings opened to respectively correspond to the plurality of first sub-pixels R1, R1′, a plurality of second openings opened to respectively correspond to the plurality of second sub-pixels R2, R2′, and a plurality of third openings opened to respectively correspond to the plurality of third sub-pixels R3, R3′. In the drawings, none of reference symbols indicating the first openings, the second openings, and the third openings is shown.

In the second pixel area PA2, one of the plurality of second sub-pixels R2, R2′ may overlap with one of the plurality of second openings, and the other of the plurality of second sub-pixels R2, R2′ may partially overlap with the other of the plurality of second openings. In the third pixel area PA3, one of the plurality of third sub-pixels R3, R3′ may overlap with one of the plurality of third openings, and the other of the plurality of third sub-pixels R3, R3′ may partially overlap with the other of the plurality of third openings.

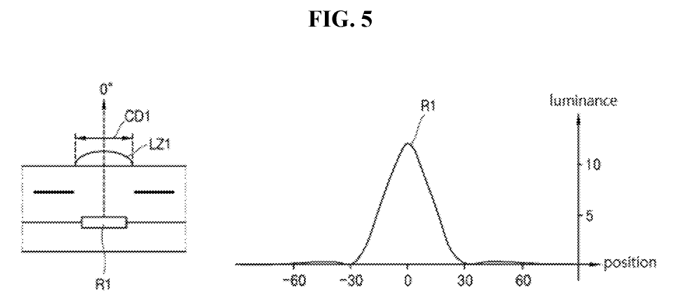

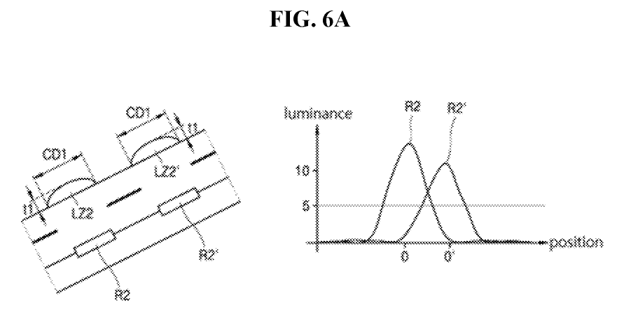

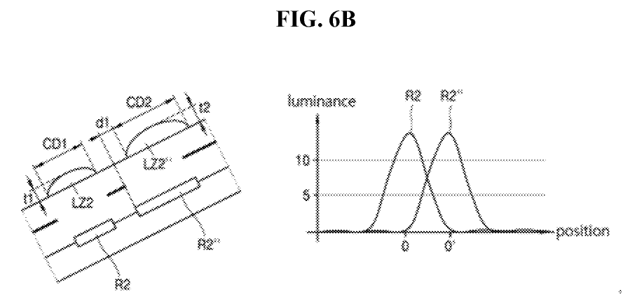

FIG. 5 is a diagram illustrating the luminance distribution through the first lens of the first sub-pixel disposed in the first pixel area according to an embodiment of the invention, and FIGS. 6A and 6B are diagrams illustrating the luminance distribution through the second lens of the second sub-pixel disposed in the second pixel area according to an embodiment of the invention.

Referring to FIG. 5, the first lens LZ1 may be disposed to vertically correspond to and overlap with the first-first sub-pixel R1.

The first lens LZ1 may have a first diameter CD1, and the width of the first-first sub-pixel R1 may be less than the first diameter CD1. For example, the first lens LZ1 may be disposed to entirely cover the first-first sub-pixel R1.

Light emitted from the first-first sub-pixel R1 may be output through the center of the first lens LZ1 at an emission angle of 0°. When the central position of the first-first sub-pixel R1 coincides with the central position of the first lens LZ1 and the emitted light is output at an emission angle of 0°, the light emitted from the first-first sub-pixel R1 may have the highest luminance value, for example, a luminance value of 10 nits or more.

Referring to FIGS. 3, 6A, and 6B, in the second pixel area PA2, when the display panel 10 is bent with the first curvature CR1 from the curvature reference line CRL, the second-first lens LZ2 may be disposed to vertically correspond to and overlap with the second-first sub-pixel R2, and the second-second lens LZ2′ may be disposed to vertically correspond to and overlap with the second-second sub-pixel R2′.

Light emitted from the second-first sub-pixel R2 may be transmitted through the second-first lens LZ2 to be output. Light emitted from the second-second sub-pixel R2' may be transmitted through the second-second lens LZ2' to be output.

As shown in FIG. 6A, the second-first lens LZ2 and the second-second lens LZ2′ may have the same first diameter CD1 and the same first thickness t1. Additionally, the second-first sub-pixel R2 and the second-second sub-pixel R2′ may have the same width and thickness.

As a result of this, the light emitted from the second-first sub-pixel R2 and the light emitted from the second-second sub-pixel R2′ may have different luminance values. For example, the light emitted from the second-first sub-pixel R2 may have a luminance value of 10 nits or more, and the light emitted from the second-second sub-pixel R2′ may have a luminance value of less than 10 nits.

As shown in FIG. 6B, in the display panel, there may be disposed a second-first sub-pixel R2 and a second-3 sub-pixel R2″, a second-first lens LZ2 may be disposed to vertically correspond to and overlap with the second-first sub-pixel R2, and a second-3 lens LZ2″ may be disposed to vertically correspond to and partially overlap with the second-3 sub-pixel R2″.

In this regard, the second-3 lens LZ2″ may be disposed to be shifted by a first distance d1 in the direction from the second-3 sub-pixel R2″ to the first pixel area PA1 so that only a part, rather than the entirety, overlaps.

The light emitted from the second-first sub-pixel R2 may be transmitted through the second-first lens LZ2 to be output, and the light emitted from the second-3 sub-pixel R2″ may be transmitted through the second-3 lens LZ2″ to be output.

As shown in of FIG. 6B, the second-first lens LZ2 may have a first diameter CD1 and a first thickness t1, while the second-3 lens LZ2″ may have a second diameter CD2 and a second thickness t2. Additionally, the second-first sub-pixel R2 and the second-3 sub-pixel R2″ may have different widths. Here, the second width CD2 may have a greater value than the first diameter CD1, and the second thickness t2 may have a greater value than the first thickness t1.

Thus, the second-3 lens LZ2″ may have a greater second diameter CD2 and a greater second thickness t2 than the second-first lens LZ2, and the second-3 sub-pixel R2″ may have a greater width than the second-first sub-pixel R2.

Accordingly, the light emitted from the second-first sub-pixel R2 and the light emitted from the second-3 sub-pixel R2″ may have the same luminance value as each other. For example, the light emitted from the second-first sub-pixel R2 may have a luminance value of 10 nits or more, and the light emitted from the second-3 sub-pixel R2" may have the same luminance value of 10 nits or more.

Referring to FIGS. 6A and 6B, in the state of being bent with the first curvature CR1 in the second pixel area PA2, as shown in FIG. 6A, the lights emitted from sub-pixels of the same size will have different luminance values when passing through lenses of the same size, whereas, as shown in FIG. 6B, by disposing the larger sub-pixel and lens at the same positions compared to before, the lights emitted from the sub-pixels of different sizes may have the same luminance value when passing through lenses of different sizes. In other words, although the second-second sub-pixel R2′ and the second-3 sub-pixel R2″ are located at the same position, the luminance value may be increased depending on the size of the sub-pixels and the size of the lenses.

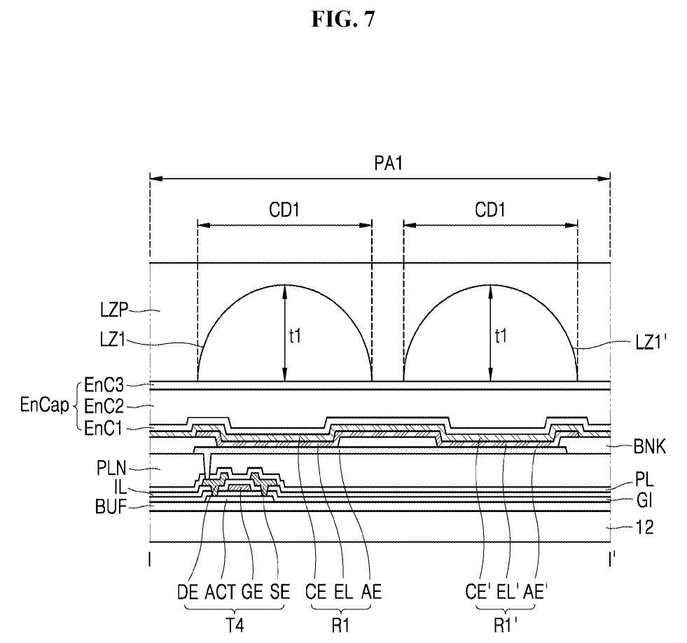

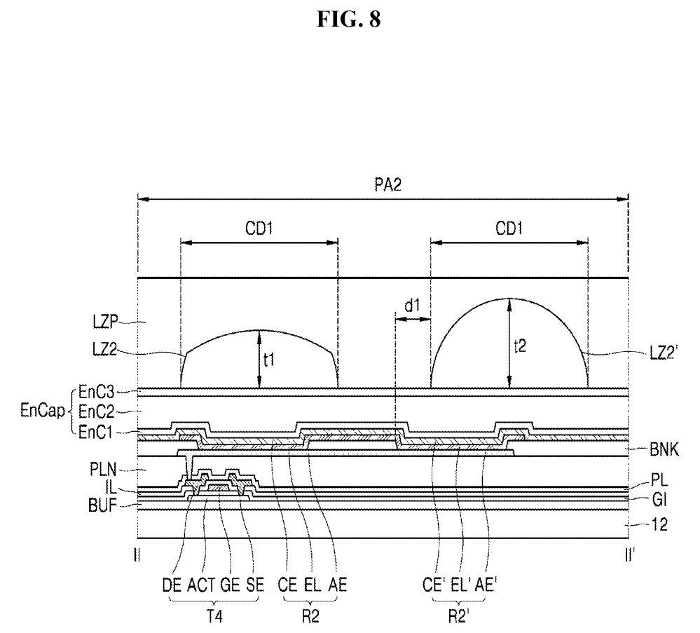

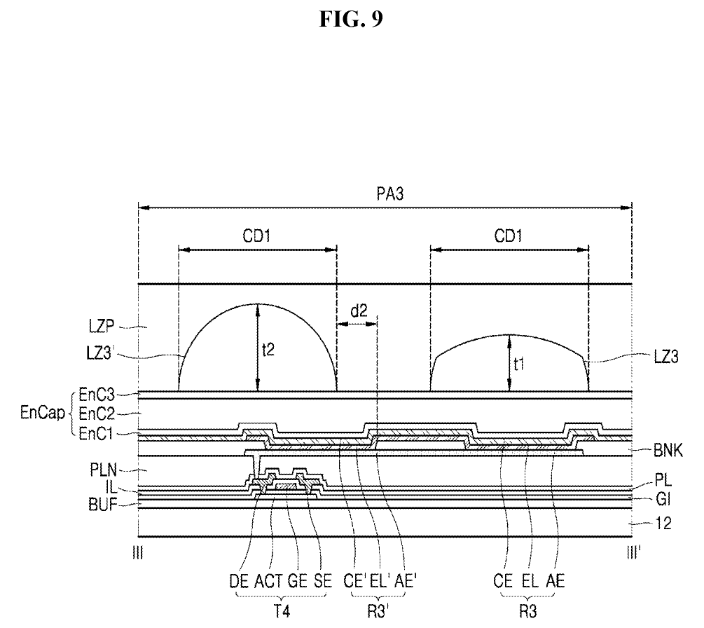

FIG. 7 is a cross-sectional view of the first pixel area taken along line I-I’ of FIG. 2 according to an embodiment of the invention; FIG. 8 is a cross-sectional view of the second pixel area taken along line II-II’ of FIG. 2 according to an embodiment of the invention; and FIG. 9 is a cross-sectional view of the third pixel area taken along line III-III’ of FIG. 2 according to an embodiment of the invention.

Referring to FIG. 7, the first pixel area PA1 according to an embodiment of the invention may include a light-emitting transistor T4, a first-first sub-pixel R1 and a first-second sub-pixel R1′ connected to the light-emitting transistor T4, and a plurality of first-first lenses LZ1 and first-second lenses LZ1′ disposed to overlap with the first-first sub-pixel R1 and the first-second sub-pixel R1′, respectively.

In the display panel according to an embodiment of the invention, a circuit element layer disposed on the second substrate 12 may include a plurality of insulating layers stacked on the second substrate 12. For example, the plurality of insulating layers may include a buffer layer BUF, a gate insulation layer GI, an interlayer insulation layer IL, a protection layer PL, and a planarization layer PLN.

The second substrate 12 may include an insulating material, such as glass or plastic. The plastic substrate may be formed of a flexible material. For example, the second substrate 12 may include at least one organic insulating material selected from acrylic resin, epoxy resin, siloxane-based resin, polyimide-based resin, or polyamide-based resin.

The buffer layer BUF may have a single-layer or multi-layer structure that includes inorganic insulating material such as silicon oxide (SiOₓ), silicon nitride (SiNₓ), or aluminum oxide (Al₂O₃). The buffer layer BUF may prevent the infiltration of impurities such as hydrogen into the semiconductor layer ACT through the substrate 12.

The light-emitting transistor T4 may be disposed on the buffer layer BUF.

The light-emitting transistor T4 includes a semiconductor layer ACT disposed on the buffer layer BUF, a gate electrode GE, a source electrode SE, and a drain electrode DE. Between the semiconductor layer ACT and the gate electrode GE, a gate insulation layer GI is disposed. Between the gate electrode GE and the source and drain electrodes SE, DE, an interlayer insulation layer IL is disposed. The source electrode SE and the drain electrode DE of the light-emitting transistor T4 may be connected to the source and drain regions of the semiconductor layer ACT, respectively, through contact holes penetrating both the interlayer insulation layer IL and the gate insulation layer GI.

The semiconductor layer ACT may include polycrystalline silicon or an oxide semiconductor material. The semiconductor layer ACT may include low-temperature polycrystalline silicon (LTPS). The semiconductor layer ACT may also include at least one oxide semiconductor material selected from IZO (InZnO), IGO (InGaO), ITO (InSnO), IGZO (InGaZnO), IGZTO (InGaZnSnO), GZTO (GaZnSnO), GZO (GaZnO), and ITZO (InSnZnO). Under the semiconductor layer ACT, a light-blocking layer (not shown) may also be further disposed.

The gate insulation layer GI may include inorganic insulating materials such as silicon oxide (SiOₓ) and silicon nitride (SiNₓ). The gate insulation layer GI may include materials with a high dielectric constant. For example, the gate insulation layer GI may include a high-K material, such as hafnium oxide (HfO). The gate insulation layer GI may have a multi-layer structure.

On the gate insulation layer GI, gate lines (not shown) connected to the gate electrode GE may be disposed.

The interlayer insulation layer IL may include inorganic insulating materials such as silicon oxide (SiOₓ) and silicon nitride (SiNₓ). The interlayer insulation layer IL may have a multi-layer structure.

On the interlayer insulation layer IL, data lines (not shown) and power lines (not shown) that are connected to the source electrode SE or the drain electrode DE may be disposed.

On the light-emitting transistor T4, the protection layer PL and the planarization layer PLN may be stacked. The protection layer PL may include inorganic insulating materials, such as silicon oxide (SiOₓ) and silicon nitride (SiNₓ). The planarization layer PLN may include the protection layer PL and other organic insulating material, and provide a flat surface.

On the planarization layer PLN, a light-emitting device layer including the first-first sub-pixel R1 and the first-second sub-pixel R1′ may be disposed.

The first-first sub-pixel R1 includes a first electrode AE disposed on the planarization layer PLN, a light-emitting layer EL disposed on the first electrode AE, and a second electrode CE disposed on the light-emitting layer EL. The first-second sub-pixel R1′ includes a first electrode AE′ disposed on the planarization layer PLN, a light-emitting layer EL′ disposed on the first electrode AE′, and a second electrode CE′ disposed on the light-emitting layer EL′. The first-first sub-pixel R1 and the first-second sub-pixel R1′ disposed in the first pixel area PA1 may, for example, emit light of the same red color.

The first electrode AE of the first-first sub-pixel R1 may be connected to either the source electrode SE or the drain electrode DE of the light-emitting transistor T4 through a contact hole penetrating the planarization layer PLN and the protection layer PL. The first electrode AE′ of the first-second sub-pixel R1′ may be connected to either the source electrode SE or the drain electrode DE of the light-emitting transistor T4 through the contact hole penetrating the planarization layer PLN and the protection layer PL. The first electrode AE of the first-first sub-pixel R1 and the first electrode AE′ of the first-second sub-pixel R1′ may be integrally formed in the same layer. That is, the first electrode AE′ of the first-second sub-pixel R1′ may be formed by being extended from the first electrode AE of the first-first sub-pixel R1. However, the inventive concepts are not limited to this. For example, the first electrode AE of the first-first sub-pixel R1 and the first electrode AE′ of the first-second sub-pixel R1′ may be spaced apart from each other by a certain distance.

The first electrodes AE, AE′ may include conductive material with high reflectivity. The first electrodes AE, AE′ may include metal, such as aluminum (Al), silver (Ag), titanium (Ti), or an alloy of silver-palladium-copper (APC). The first electrodes AE, AE′ may further include transparent conductive material, such as ITO (Indium Tin Oxide) or IZO (Indium Zinc Oxide). For example, the first electrodes AE, AE′ may have a multi-layer structure (Ti/Al/Ti) of titanium (Ti) and aluminum (Al), a multi-layer structure (ITO/Al/ITO) of ITO and aluminum (Al), or a multi-layer structure (ITO/APC/ITO) of ITO and APC. The first electrode AE, AE′ may be, for example, an anode electrode.

The light-emitting layer EL, EL′ may include a light-emitting material layer EML including light-emitting material. The light-emitting material may include organic material, inorganic material, or hybrid material. The light-emitting layer EL of the first-first sub-pixel R1 and the light-emitting layer EL′ of the first-second sub-pixel R1′ may be integrally formed. That is, the light-emitting layer EL′ of the first-second sub-pixel R1′ may be formed by being extended from the light-emitting layer EL of the first-first sub-pixel R1. However, the inventive concepts are not limited to this. For example, the light-emitting layer EL of the first-first sub-pixel R1 and the light-emitting layer EL′ of the first-second sub-pixel R1′ may be spaced apart by a certain distance. Thereby, it is possible to prevent light emission by leakage current.

The light-emitting layer EL, EL′ may have a multi-layer structure. For example, the light-emitting layer EL, EL′ may further include at least one of a hole injection layer (HIL), a hole transport layer (HTL), an electron transport layer (ETL), and an electron injection layer (EIL).

The second electrode CE, CE′ may include conductive material capable of transmitting light. The second electrode CE, CE′ may include transparent conductive material, such as ITO (Indium Tin Oxide) or IZO (Indium Zinc Oxide). The second electrode CE, CE′ may include aluminum (Al), magnesium (Mg), silver (Ag), or their alloys, and may be so thin so as to transmit light. As a result, light generated by the light-emitting layer EL, EL’ may be emitted through each of the second electrodes CE, CE′.

The first electrode AE of the first-first sub-pixel R1 and the first electrode AE′ of the first-second sub-pixel R1′ may be integrally formed. That is, the first electrode AE′ of the first-second sub-pixel R1′ may be formed on the planarization layer PLN by being extended from the first electrode AE of the first-first sub-pixel R1. However, the inventive concepts are not limited to this. For example, the first electrode AE of the first-first sub-pixel R1 and the first electrode AE′ of the first-second sub-pixel R1′ may be spaced apart from each other in the same layer by a certain distance.

On the first electrode AE of the first-first sub-pixel R1 and the first electrode AE′ of the first-second sub-pixel R1′, which are integrally formed, the bank layer BNK may be disposed between the light-emitting layer EL of the first-first sub-pixel R1 and the light-emitting layer EL′ of the first-second sub-pixel R1′. That is, the light-emitting layer EL of the first-first sub-pixel R1 and the light-emitting layer EL′ of the first-second sub-pixel R1′ may have their emission regions separated and distinguished by the bank layer BNK.

The bank layer BNK may cover edges of each of the first electrodes AE, AE′. The bank layer BNK may include organic insulating material. The bank layer BNK may be disposed on a planarization layer PLN and other organic material, and may have a single-layer or double-layer structure.

The bank layer BNK may have openings through which the first electrodes AE, AE′ are exposed, thereby defining the first-first emission region and the first-second emission region. In an embodiment, the bank layer BNK may have an opening through which the first electrode AE of the first-first sub-pixel R1 is exposed, thereby defining the first-first emission region. In an embodiment, the bank layer BNK may have an opening through which the first electrode AE' of the first-second sub-pixel R1' is exposed, thereby defining the first-second emission region.

The light-emitting layer EL and the second electrode CE of the first-first sub-pixel R1 may be stacked on the first electrode AE exposed through the opening of the bank layer BNK. The light-emitting layer EL′ and the second electrode CE′ of the first-second sub-pixel R1′ may be stacked on the first electrode AE′ exposed through the opening of the bank layer BNK. In this regard, as described above, the two first electrodes AE, AE′ are integrally formed, and the two light-emitting layers EL, EL′ are also integrally formed.

The second electrode CE of the first-first sub-pixel R1 may be a common electrode electrically connected to the second electrode CE′ of the first-second sub-pixel R1′. The second electrode CE of the first-first sub-pixel R1 and the second electrode CE′ of the first-second sub-pixel R1′ may be integrally formed on the bank layer BNK and the light-emitting layers EL, EL′. The second electrode CE′ of the first-second sub-pixel R1′ may be formed on the bank layer BNK and the light-emitting layers EL, EL′ by being extended from the second electrode CE of the first-first sub-pixel R1.

In the first pixel area PA1, on the light-emitting device layer including the first-first sub-pixel R1 and the first-second sub-pixel R1′, an encapsulation layer EnCap may be located. The encapsulation layer EnCap may prevent damage to the light-emitting layers EL, EL′ caused by moisture and shocks from the outside. The encapsulation layer EnCap may have a multi-layer structure. For example, the encapsulation layer EnCap may include a first encapsulation layer EnC1, a second encapsulation layer EnC2, and a third encapsulation layer EnC3 which are stacked in this order, although embodiments of the invention are not limited to this. The first encapsulation layer EnC1, the second encapsulation layer EnC2, and the third encapsulation layer EnC3 may include insulating material. The second encapsulation layer EnC2 may include a different material from the first encapsulation layer EnC1 and the third encapsulation layer EnC3. For example, the first encapsulation layer EnC1 and the third encapsulation layer EnC3 may be inorganic encapsulation layers that include inorganic insulating material, while the second encapsulation layer EnC2 may be an organic encapsulation layer that includes organic insulating material. As a result, it is possible to more effectively protect the light-emitting layers EL, EL′ of the display device from damage caused by moisture and shocks from the outside.

In the first pixel area PA1, on top of the encapsulation layer EnCap, a lens layer including the first-first lens LZ1 and the first-second lens LZ1′ may be disposed. The first-first lens LZ1 and the first-second lens LZ1′ may have the same shape, the same diameter CD1, and the same thickness t1 as each other.

The first-first lens LZ1 may be disposed on the encapsulation layer EnCap so that it overlaps with the first-first sub-pixel R1. In other words, the first-first lens LZ1 may be disposed to overlap with all of the first electrode AE, the light-emitting layer EL, and the second electrode CE of the first-first sub-pixel R1.

The first-second lens LZ1' may be disposed on the encapsulation layer EnCap so that it overlaps with the first-second sub-pixel R1'. In other words, the first-second lens LZ1' may be disposed to overlap with all of the first electrode AE', the light-emitting layer EL', and the second electrode CE' of the first-first sub-pixel R1'.

In the first pixel area PA1, on the first-first lens LZ1 and the first-second lens LZ1′, a lens protection layer LZP may be positioned. The lens protection layer LZP may include organic insulating material. The refractive index of the lens protection layer LZP may be smaller than the refractive indices of the first-first lens LZ1 and the first-second lens LZ1′. As a result, it is possible to prevent the lights passing through the first-first lens LZ1 and the first-second lens LZ1′ from being reflected toward the substrate 12 due to the difference in refractive index with the lens protection layer LZP.

Referring to FIG. 8, the second pixel area PA2 according to an embodiment of the invention may include a light-emitting transistor T4, a second-first sub-pixel R2 and a second-second sub-pixel R2′ connected to the light-emitting transistor T4, and a plurality of second-first lenses LZ2 and second-second lenses LZ2′ disposed to overlap with the second-first sub-pixel R2 and the second-second sub-pixel R2′, respectively.

In FIG. 8, the light-emitting layer EL of the second-first sub-pixel R2 and the light-emitting layer EL′ of the second-second sub-pixel R2′ may be integrally formed. That is, the light-emitting layer EL′ of the second-second sub-pixel R2′ may be formed by being extended from the light-emitting layer EL of the second-first sub-pixel R2. However, the inventive concepts are not limited to this. For example, the light-emitting layer EL of the second-first sub-pixel R2 and the light-emitting layer EL′ of the second-second sub-pixel R2′ may be spaced apart by a certain distance.

In FIG. 8, the first electrode AE of the second-first sub-pixel R2 and the first electrode AE′ of the second-second sub-pixel R2′ may be integrally formed. That is, the first electrode AE′ of the second-second sub-pixel R2′ may be formed by being extended from the first electrode AE of the second-first sub-pixel R2. However, the inventive concepts are not limited to this. For example, the first electrode AE of the second-first sub-pixel R2 and the first electrode AE′ of the second-second sub-pixel R2′ may be spaced apart from each other in the same layer by a certain distance.

In FIG. 8, the second electrode CE of the second-first sub-pixel R2 and the second electrode CE′ of the second-second sub-pixel R2′ may be integrally formed. That is, the second electrode CE′ of the second-second sub-pixel R2′ may be formed by being extended from the second electrode CE of the second-first sub-pixel R2. However, the inventive concepts are not limited to this. For example, the second electrode CE of the second-first sub-pixel R2 and the second electrode CE′ of the second-second sub-pixel R2′ may be spaced apart from each other in the same layer by a certain distance.

In FIG. 8, the description of components disposed in the same location and having the same structure as those shown in FIG. 7 will be omitted. For example, the second-first sub-pixel R2 in FIG. 8 corresponds to the first-first sub-pixel R1 in FIG. 7 and has the same structure, and the second-second sub-pixel R2′ corresponds to the first-second sub-pixel R1′ in FIG. 7 and has the same structure, so the description of these components will be omitted.

In FIG. 8, on the encapsulation layer EnCap, the second-first lens LZ2 may be disposed to correspond to and overlap with the second-first sub-pixel R2, and the second-second lens LZ2′ may be disposed to correspond to and overlap with the second-second sub-pixel R2′.

In this regard, the second-first lens LZ2 and the second-second lens LZ2' may have the same first diameter CD1.

However, the second-first lens LZ2 and the second-second lens LZ2' may have different thicknesses t1, t2. For example, the second-first lens LZ2 may have the first thickness t1, but the second-second lens LZ2' may have a second thickness t2 greater than the first thickness t1.

The second-first lens LZ2 may be disposed to overlap with the second-first sub-pixel R2 so that it may entirely cover the second-first sub-pixel R2. For example, the second-first lens LZ2 may be disposed to overlap with the second-first sub-pixel R2 so that it may entirely cover the first electrode AE, the emission layer EL, and the second electrode CE of the second-first sub-pixel R2.

The second-second lens LZ2' may not entirely overlap with the second-second sub-pixel R2', but may be disposed to be shifted by the first distance d1 in the direction from one side end of the second-second sub-pixel R2' to the first pixel area PA, thereby partially overlapping with the second-second sub-pixel R2'.

Referring to FIG. 9, the third pixel area PA3 according to an embodiment of the invention may include a light-emitting transistor T4, a third-first sub-pixel R3 and a third-second sub-pixel R3′ connected to the light-emitting transistor T4, and a plurality of third-first lenses LZ3 and third-second lenses LZ3′ disposed to overlap with the third-first sub-pixel R3 and the third-second sub-pixel R3′, respectively.

In FIG. 9, the light-emitting layer EL of the third-first sub-pixel R3 and the light-emitting layer EL′ of the third-second sub-pixel R3′ may be integrally formed. That is, the light-emitting layer EL′ of the third-second sub-pixel R2′ may be formed by being extended from the light-emitting layer EL of the third-first sub-pixel R3. However, the inventive concepts are not limited to this. For example, the light-emitting layer EL of the third-first sub-pixel R3 and the light-emitting layer EL′ of the third-second sub-pixel R3′ may be spaced apart by a certain distance.

In FIG. 9, the first electrode AE of the third-first sub-pixel R3 and the first electrode AE′ of the third-second sub-pixel R3′ may be integrally formed. That is, the first electrode AE′ of the third-second sub-pixel R3′ may be formed by being extended from the first electrode AE of the third-first sub-pixel R3. However, the inventive concepts are not limited to this. For example, the first electrode AE of the third-first sub-pixel R3 and the first electrode AE′ of the third-second sub-pixel R3′ may be spaced apart from each other in the same layer by a certain distance.

In FIG. 9, the second electrode CE of the third-first sub-pixel R3 and the second electrode CE′ of the third-second sub-pixel R3′ may be integrally formed. That is, the second electrode CE′ of the third-second sub-pixel R3′ may be formed by being extended from the second electrode CE of the third-first sub-pixel R3. However, the inventive concepts are not limited to this. For example, the second electrode CE of the third-first sub-pixel R3 and the second electrode CE′ of the third-second sub-pixel R3′ may be spaced apart from each other in the same layer by a certain distance.

In FIG. 9, the description of components disposed in the same location and having the same structure as those shown in FIGS. 7 and 8 will be omitted. For example, the third-first sub-pixel R3 in FIG. 9 corresponds to the second-first sub-pixel R2 in FIG. 8 and has the same structure, and the third-second sub-pixel R3′ corresponds to the second-second sub-pixel R2′ in FIG. 8 and has the same structure, so the description of these components will be omitted.

In FIG. 9, on the encapsulation layer EnCap, the third-first lens LZ3 may be disposed to correspond to and overlap with the third-first sub-pixel R3, and the third-second lens LZ3′ may be disposed to correspond to and overlap with the third-second sub-pixel R3′.

In this regard, the third-first lens LZ3 and the third-second lens LZ3' may have the same first diameter CD1.

However, the third-first lens LZ3 and the third-second lens LZ3' may have different thicknesses t1, t2. For example, the third-first lens LZ3 may have the first thickness t1, but the third-second lens LZ3' may have a second thickness t2 greater than the first thickness t1.

The third-first lens LZ3 may be disposed to overlap with the third-first sub-pixel R3 so that it may entirely cover the third-first sub-pixel R3. For example, the third-first lens LZ3 may be disposed to overlap with the third-first sub-pixel R3 so that it may entirely cover the first electrode AE, the emission layer EL, and the second electrode CE of the third-first sub-pixel R3.

The third-second lens LZ3' may not entirely overlap with the third-second sub-pixel R3', but may be disposed to be shifted by the second distance d2 in the direction from one side end of the third-second sub-pixel R3' to the first pixel area PA, thereby partially overlapping with the third-second sub-pixel R3'.

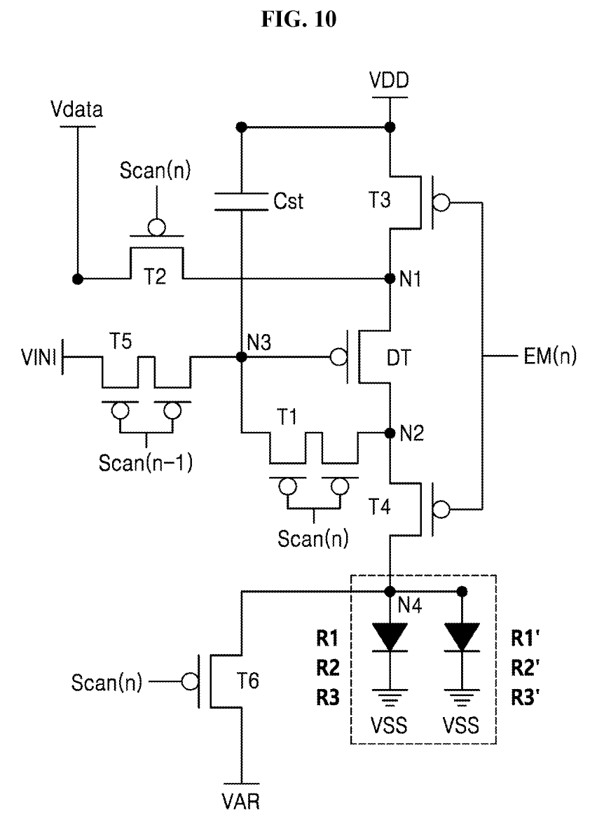

FIG. 10 is a diagram showing the pixel circuit of each sub-pixel according to an embodiment of the invention.

Referring to FIG. 10, the pixel circuit of each sub-pixel R1, R1', R2, R2', R3, R3' according to an embodiment of the invention may have one side connected to the light-emitting transistor T4, and the other side connected to a low-potential voltage VSS.

The first electrode of the light-emitting transistor T4 may be either one of the source electrode and the drain electrode, and the second electrode of the light-emitting transistor T4 may be the remaining one of the source electrode and the drain electrode.

Each sub-pixel R1, R1’, R2, R2’, R3, R3’ may be supplied with a high-potential voltage VDD, a low-potential voltage VSS, an initialization voltage VINI, and an anode reset voltage VAR, and may receive a scan signal Scan(n), Scan(n-1), an emission signal EM(n), and a data voltage signal Vdata as inputs. Additionally, although not shown, each sub-pixel R1, R1’, R2, R2’, R3, R3’ may be supplied with an on-bias stress (OBS) voltage Vobs.

One pixel circuit may include organic light-emitting diodes (OLED), a driving TFT DT, a capacitor Cst, a first TFT T1, a second TFT T2, a third TFT T3, a fourth TFT T4, a fifth TFT T5, and a sixth TFT T6.

Each of the TFTs may be constituted with a p-type MOSFET (PMOS) or an n-type MOSFET (NMOS). For example, the driving TFT DT, the first TFT T1 to the sixth TFT T6 may be implemented in a p-type, and the remaining TFTs may be implemented in an n-type, but the inventive concepts are not limited to this.

Each of the sub-pixels R1, R1′, R2, R2′, R3, and R3′ may include each of the OLEDs. The OLED emits light by the driving current supplied from the driving TFT DT. The anode electrode of the OLED is connected to the fourth node N4, and the cathode electrode of the OLED is connected to a line to which the low-potential voltage VSS is provided.

The third TFT T3 and the fourth TFT T4 may be light-emitting control transistors for controlling light emission of the OLED. It may simply be referred to as a “light-emitting transistor”.

The driving TFT DT has a gate electrode connected to the third node N3, a first electrode connected to the first node N1, and a second electrode connected to the second node N2. The driving TFT DT may generate a driving current in response to the data voltage signal Vdata. The driving TFT DT may be a p-type MOSFET (PMOS), and may be implemented as a low-temperature polycrystalline silicon (LTPS) thin film transistor.

The third TFT T3 and the fourth TFT T4 are for controlling light emission of the OLED. The third TFT T3 and the fourth TFT T4 are controlled such that they may be simultaneously turned on/off according to the emission signal EM(n) input to each gate electrode at the same time. The third TFT T3 has a first electrode connected to the high-potential voltage VDD and a second electrode connected to the first node N1. The third TFT T3 may serve to transmit the high-potential voltage VDD to the first electrode of the driving TFT DT in response to the light emission signal EM(n). The fourth TFT T4 may have a first electrode connected to the second node N2 and a second electrode connected to the fourth node N4. The fourth TFT T4 may serve to transmit a driving current to the anode electrode of the OLED in response to the emission signal EM(n). The third TFT T3 and the fourth TFT T4 may be p-type MOSFETs (PMOSs) and may be implemented as low-temperature polycrystalline silicon (LTPS) thin film transistors.

The storage capacitor Cst maintains the data voltage Vdata stored in the sub-pixel during one frame. The storage capacitor Cst has one electrode connected to the third node N3 to which the gate electrode of the driving TFT DT is connected, and the other electrode connected to the high-potential voltage VDD.

The second TFT T2 applies the data voltage signal Vdata to the first node N1, which is the first electrode of the driving TFT DT. The second TFT T2 may include a gate electrode connected to an input line of the nth scan signal Scan(n), a first electrode connected to a data line to which the data voltage signal Vdata is supplied, and a second electrode connected to the first node N1. The second TFT T2 may be a p-type MOSFET (PMOS), and may be implemented as a low-temperature polycrystalline silicon (LTPS) thin film transistor. Accordingly, the second TFT T2 applies the data voltage signal Vdata supplied from the data line to the first node N1, which is the first electrode of the driving TFT DT, in response to the nth scan signal Scan(n) of the low level, which is the turn-on voltage.

The first TFT T1 diode-connects the driving TFT DT by connecting the gate electrode of the driving TFT DT and the drain electrode thereof, which is the second electrode. The first TFT T1 may include a gate electrode connected to the input line of the nth scan signal Scan(n), a first electrode connected to the third node N3, and a second electrode connected to the second node N2. The first TFT T1 may be a p-type MOSFET (PMOS), and may be implemented as a low-temperature polycrystalline silicon (LTPS) thin film transistor. Accordingly, the first TFT T1 diode-connects the gate electrode and the drain electrode of the driving TFT DT in response to the nth scan signal Scan(n) of the low level, which is the turn-on voltage. However, the inventive concepts are not limited to this, and the first TFT T1 may be an n-type MOSFET (NMOS) and be implemented as an oxide thin film transistor, in order to minimize leakage current during the turn-off period.

The fifth TFT T5 applies the initialization voltage VINI to the third node N3, which is a gate electrode of the driving TFT DT. The fifth TFT T5 may include a gate electrode connected to the input line of the n-1th scan signal Scan(n-1), a first electrode connected to the initialization voltage VINI, and a second electrode connected to the third node N3. The fifth TFT T5 may be a p-type MOSFET (PMOS), and may be implemented as a low-temperature polycrystalline silicon (LTPS) thin film transistor. Accordingly, the fifth TFT T5 applies the initialization voltage VINI to the third node N3, which is the gate electrode of the driving TFT DT, in response to the n-1th scan signal Scan(n-1) of the low level, which is the turn-on voltage. However, the fifth TFT T5 is not limited to this, and may be an n-type MOSFET (NMOS) and be implemented as an oxide thin film transistor, in order to minimize leakage current.

The sixth TFT T6 applies the anode reset voltage VAR to the anode electrode of the OLED. The sixth TFT T6 may include a gate electrode connected to the input line of the nth scan signal Scan(n), a first electrode connected to the anode reset voltage VAR, and a second electrode connected to the fourth node N4. The sixth TFT T6 may be a p-type MOSFET (PMOS), and may be implemented as a low-temperature polycrystalline silicon (LTPS) thin film transistor. Accordingly, the sixth TFT T6 applies the anode reset voltage VAR to the anode electrode of the OLED in response to the nth scan signal Scan(n) of the low level, which is the turn-on voltage.

Although not shown in the drawings, a switching TFT for applying the OBS voltage Vobs to the first electrode of the driving TFT DT may be connected to the first node N1. The switching TFT may include a gate electrode connected to the input line of the nth scan signal Scan(n), a first electrode connected to the OBS voltage Vobs, and a second electrode connected to the first node N1. The switching TFT may be a p-type MOSFET (PMOS), and may be implemented as a low-temperature polycrystalline silicon (LTPS) thin film transistor. Accordingly, the switching TFT applies the OBS voltage Vobs to the first electrode of the driving TFT DT in response to the nth scan signal Scan(n) of the low level, which is the turn-on voltage.

The pixel current flowing through the driving TFT DT is determined by the gate-source voltage of the driving TFT DT during the light emission period, which is the voltage difference between the first node N1 and the third node N3. During the light emission period, the voltage of the first node N1 is fixed to the high-potential voltage VDD, but the voltage of the third node N3 is affected by the off characteristics of the fifth TFT T5. This is because the third node N3 is in a floating state due to the off of the fifth TFT T5 during the light emission period. Therefore, the fifth TFT T5 may be implemented as an n-type oxide transistor having good off characteristics (i.e., low off current).

Additionally, the first TFT T1 that maintains the off state during the light emission period may also be implemented as an n-type oxide transistor with good off characteristics (i.e., low off current) because the coupling action through the storage capacitor Cst may affect the voltage of the third node N3.

On the other hand, since the driving TFT DT generates a pixel current, it may be implemented as a p-type LTPS (Low Temperature Poly Silicon) transistor with good electron mobility characteristics. Likewise, the second TFT T2, the third TFT T3, the fourth TFT T4, and the sixth TFT T6 may also be implemented as p-type LTPS transistors.

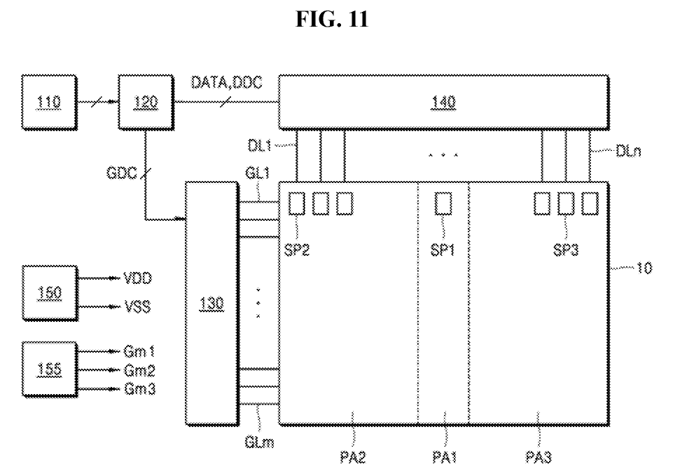

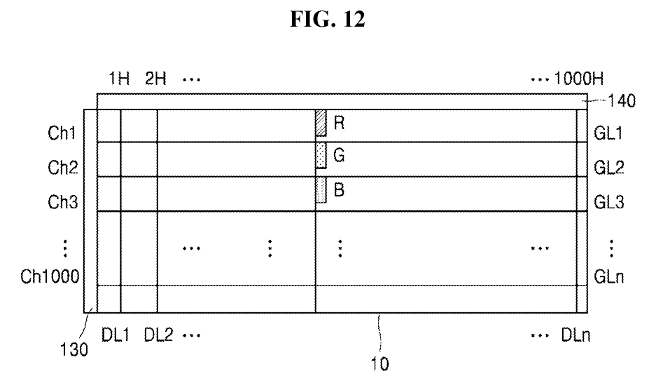

FIG. 11 is a block diagram schematically illustrating a display device for driving a display panel according to an embodiment of the invention, and FIG. 12 is a diagram schematically illustrating a wiring structure of a display panel according to an embodiment of the invention.

Referring to FIG. 11, the display device according to an embodiment of the invention may include a display panel 10, an image supply part 110, a timing controller 120, a gate driver 130, a data driver 140, a power supply part 150, a gamma driver 155, and the like.

Since the display panel 10 has been described with reference to FIGS. 1-10, a detailed description thereof will be omitted. In the display panel 10, a plurality of data lines DL1 to DLn extending in a column direction (or a vertical direction) and a plurality of gate lines GL1 to GLm extending in a row direction (or a horizontal direction) intersect with each other, and sub-pixels SP1, SP2, and SP3 are disposed at every intersecting area in the form of a matrix to form a pixel array. The sub-pixels SP disposed on the same pixel line operate simultaneously according to the scan signal Scan(n) and the emission signal EM(n) applied from the same gate line GL. Each sub-pixel SP includes a light-emitting device and a pixel circuit that controls the amount of current applied to the anode of the light-emitting device. The pixel circuit may include a driving transistor that controls the amount of current so that a predetermined current may flow through the light-emitting device. The light-emitting device emits light during the emission period, and does not emit light during other periods than the emission period. In periods other than the emission period, initialization and programming of the pixel circuit, and resetting of the light-emitting device may be performed.

In an embodiment of the invention, an electrode connected to a thin film transistor TFT that controls light emission in each sub-pixel area SP1, SP2, and SP3 of the display panel 10 is referred to as a first electrode, and an electrode disposed on the front surface of the display panel 10 or to include two or more pixel regions is referred to as a second electrode. In a case where the first electrode is the anode electrode AE, the second electrode may be the cathode electrode CE, and vice versa. Hereinafter, the present invention will be described based on an example in which an anode electrode is the first electrode and a cathode electrode is the second electrode, but it is not limited to this.

In an embodiment of the invention, one pixel may include one or more sub-pixels. For example, one pixel may include two to four sub-pixels. The sub-pixel refers to a point in which a specific type of color filter layer is formed, or an organic light-emitting device may emit light of a special color without forming a color filter layer. Examples of the color defined at the sub-pixel SP may include red (R), green (G), blue (B), and optionally white (W), but the present embodiment is not limited to this.

An embodiment of the invention may practice a bottom-emission type organic light-emitting display device, but the inventive concepts are not limited to this, and may be applied to top-emission or dual-emission type organic light-emitting display devices according to necessity.

Referring to FIG. 12, in the display panel 10 according to an embodiment of the invention, n gate lines GL1 to GLn extending in a horizontal direction may be disposed at constant intervals in a vertical direction. For example, in a case where 1000 gate lines GL1 to GL1000 are disposed, the display panel 10 may have 1000 channels Ch1 to Ch1000.

Additionally, in the display panel 10 according to an embodiment of the invention, n data lines DL1 to DLn extending in the vertical direction may be disposed at constant intervals in the horizontal direction. For example, in a case where 1000 data lines DL1 to DL1000 are disposed, the display panel 10 may have 1000 data channels 1H to 1000H.

One sub-pixel among red (R), green (G), blue (B) and white (W) sub-pixels may be electrically connected to a point where one gate line GL and one data line DL intersect with each other.

One pixel according to an embodiment of the invention includes one or more sub-pixels SP. The sub-pixel SP may refer to a point in which a specific type of color filter is formed, or an organic light-emitting device may emit light of a special color without forming a color filter. Examples of the color defined at the sub-pixel may include red (R), green (G), blue (B), and optionally white (W), but the inventive concepts are not limited to this. A sub-pixel may be referred to as a sub-picture element or vice-pixel.

Referring back to FIG. 11, the image supply part 110 may output various driving signals together with an image data signal supplied from the outside or an image data signal stored in an internal memory. The image supply part 110 may supply the data signal and the various driving signals to the timing controller 120.

The timing controller 120 controls the gate driver 130 and the data driver 140. The timing controller 120 may output a gate timing control signal GDC for controlling the operation timing of the gate driver 130, a data timing control signal DDC for controlling the operation timing of the data driver 140, various synchronization signals (Vsync, which is a vertical synchronization signal, Hsync which is a horizontal synchronization signal), and the like. The timing controller 120 may supply, to the data driver 140, the data signal DATA supplied from the image supply part 110 together with the data timing control signal DDC. The timing controller 120 may be formed as an integrated circuit (IC) and mounted on a printed circuit board, but the inventive concepts are not limited to this.

The gate driver 130 applies a gate voltage to the display panel 10. Although not shown, the gate driver 130 may include a scan driver and a light-emitting driver therein. The scan driver may supply a scan signal to the display panel 10, and the light-emitting driver may supply an emission signal to the display panel 10.

The gate driver 130 may output a scan signal and an emission signal in response to the gate timing control signal GDC or the like supplied from the timing controller 120. The gate driver 130 may supply at least one scan signal and an emission signal to sub-pixels included in the display panel 10 through the gate lines GL1 to GLm. The gate driver 130 may be formed in the form of an IC or may be directly formed on the display panel 10 in a gate-in-panel manner.

The data driver 140 may sample and latch the data signal DATA in response to the data timing control signal DDC and the like supplied from the timing controller 120, may convert a digital data signal into an analog data voltage based on a gamma reference voltage, and may output the converted analog data signal. The data driver 140 may supply data voltages to sub-pixels included in the display panel 10 through the data lines DL1 to DLn. The data driver 140 may be formed as an IC and mounted on the display panel 10 or mounted on a printed circuit board, but the inventive concepts are not limited to this.

The power supply part 150 may convert power supplied from the outside into power required for driving the display device and output the converted power, under the control of the timing controller 120. For example, the power supply part 150 may convert power supplied from the outside into a high-potential voltage VDD, a low-potential voltage VSS, and the like, may output the converted voltages, and may generate and output a voltage required for driving the scan driver 130 (e.g., a gate voltage including a gate high voltage and a gate low voltage), a voltage required for driving the data driver 140 (a drain voltage including a drain voltage and a half drain voltage), and the like.

The gamma driver 155 may apply a gamma voltage to the display panel 10. Here, the gamma voltage may include a first gamma voltage Gm1, a second gamma voltage Gm2, and a third gamma voltage Gm3. Each of the first gamma voltage Gm1, the second gamma voltage Gm2, and the third gamma voltage Gm3 may be one of a gamma reference high voltage (Gamma REF_High Voltage), a gamma voltage (Gamma Voltage), and a gamma reference low voltage (Gamma REF_Low Voltage).

The gamma driver 155 may apply a first gamma voltage Gm1 to the first pixel area PA1, apply a second gamma voltage Gm2 to the second pixel area PA2, and apply a third gamma voltage Gm3 to the third area pixel PA3.

The gamma driver 155 may apply, to the second pixel area PA2, the second gamma voltage Gm2 lower than the first gamma voltage Gm1 applied to the first pixel area PA1, and apply, to the third pixel area PA3, the third gamma voltage Gm3 lower than the first gamma voltage Gm1.

The gamma driver 155 may be formed as an integrated circuit (IC) form, and be mounted on a printed circuit board, but the present invention is not limited to this.

The first gamma voltage Gm1 is greater than the second gamma voltage Gm2, and the second gamma voltage Gm2 is greater than the third gamma voltage Gm3. However, embodiments of the invention are not limited to this.

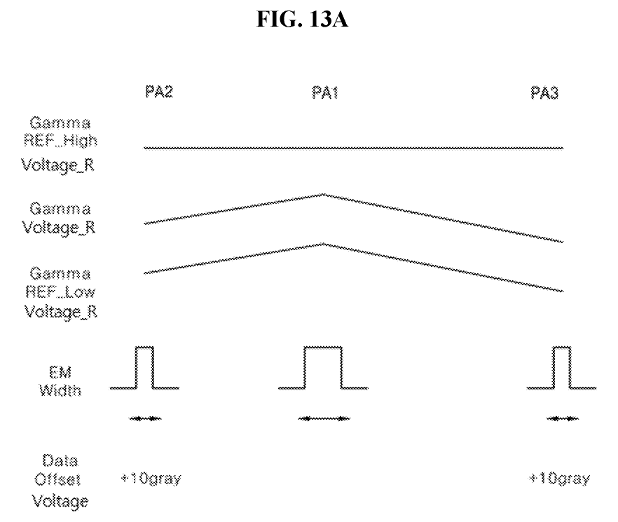

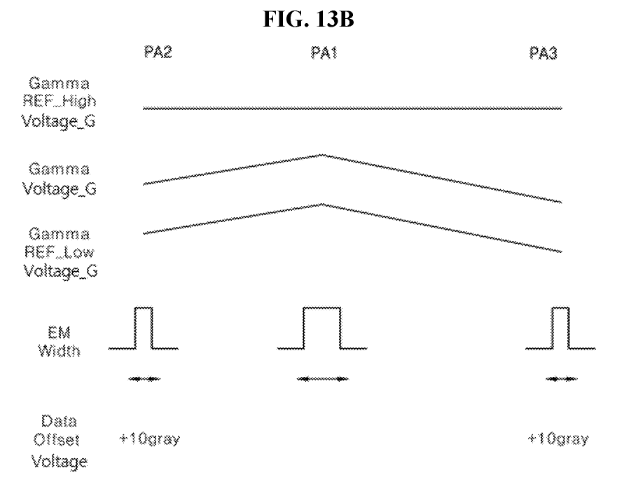

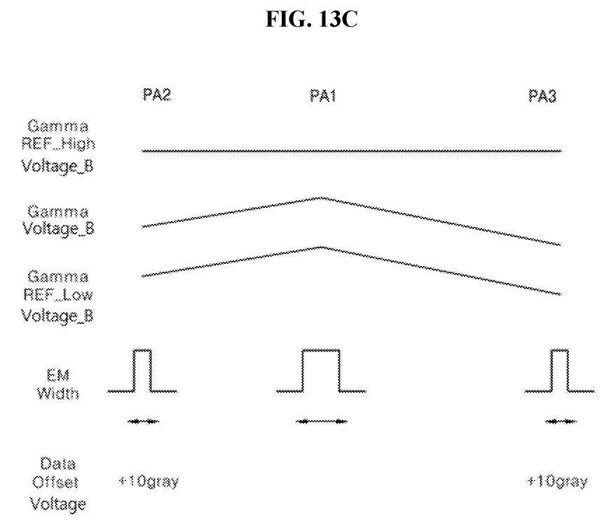

FIG. 13A is a diagram illustrating a gamma voltage, a pulse width, and an offset voltage compensating for a luminance difference of an R pixel according to an embodiment of the invention; FIG. 13B is a diagram illustrating a gamma voltage, a pulse width, and an offset voltage compensating for a luminance difference of a G pixel according to an embodiment of the invention; and FIG. 13C is a diagram illustrating a gamma voltage, a pulse width, and an offset voltage compensating for a luminance difference of a B pixel according to an embodiment of the invention.

Referring to FIGS. 13A, 13B, and 13C the gamma driver 155 may apply, to each of the first pixel area PA1, the second pixel area PA2, and the third pixel area PA3, a gamma reference high voltage (Gamma REF_High) having the same voltage level.

For example, the gamma driver 155 may supply, to the sub-pixels of the red (R) disposed in the first pixel area PA1, the second pixel area PA2, and the third pixel area PA3, the gamma reference high voltage (Gamma REF_H voltage_R) of the same level, respectively.

Additionally, the gamma driver 155 may supply, to the sub-pixels of the green (G) disposed in the first pixel area PA1, the second pixel area PA2, and the third pixel area PA3, the gamma reference high voltage (Gamma REF_H voltage_G) of the same level, respectively.

Additionally, the gamma driver 155 may supply, to the sub-pixels of the blue (B) disposed in the first pixel area PA1, the second pixel area PA2, and the third pixel area PA3, the gamma reference high voltage (Gamma REF_H voltage_B) of the same level, respectively.

The gamma driver 155 may apply, to the second and third areas PA2 and PA3, second and third gamma reference low voltages lower than the first gamma reference low voltage (Gamma REF_Low) applied to the first pixel area PA1, respectively. Here, the gamma reference low voltage applied to the first pixel area PA1 is referred to as the first gamma reference low voltage; the gamma reference low voltage applied to the second pixel area PA2 is referred to as the second gamma reference low voltage; and the gamma reference low voltage applied to the third pixel area PA3 is referred to as the third gamma reference low voltage.

Referring to FIG. 13A, as for the respective sub-pixels of the red R disposed in the first area PA1, the second area PA2, and the third area PA3, the gamma driver 155 may apply a first gamma reference low voltage to the first pixel area PA1, and supply, to the second and third pixel areas PA2 and PA3, the second and third gamma reference low voltages (Gamma REF_Low voltage_R) lower than the first gamma reference low voltages, respectively. Here, the third gamma reference low voltage (Gamma REF_Low voltage_R) may be a voltage having a lower level than the second gamma reference low voltage.

Referring to FIG. 13B, as for the respective sub-pixels of the green G disposed in the first area PA1, the second area PA2, and the third area PA3, the gamma driver 155 may apply a first gamma reference low voltage to the first pixel area PA1, and supply, to the second and third pixel areas PA2 and PA3, the second and third gamma reference low voltages (Gamma REF_Low voltage_G) lower than the first gamma reference low voltages, respectively. Here, the third gamma reference low voltage (Gamma REF_Low voltage_G) may be a voltage having a lower level than the second gamma reference low voltage.

Referring to FIG. 13C, as for the respective sub-pixels of the blue B disposed in the first area PA1, the second area PA2, and the third area PA3, the gamma driver 155 may apply a first gamma reference low voltage to the first pixel area PA1, and supply, to the second and third pixel areas PA2 and PA3, the second and third gamma reference low voltages (Gamma REF_Low voltage_B) lower than the first gamma reference low voltages, respectively. Here, the third gamma reference low voltage (Gamma REF_Low voltage_B) may be a voltage having a lower level than the second gamma reference low voltage.

The gate driver 130 according to an embodiment of the invention may include a light-emitting driver that applies a first emission signal to the first area PA1, applies a second emission signal to the second area PA2, and applies a third emission signal to the third area PA3.

Referring to FIGS. 13A, 13B, and 13C, the light-emitting driver may compensate for a luminance difference resulting from a curved curvature of each of the first pixel area PA1, the second pixel area PA2, and the third pixel area PA3 by adjusting a pulse width (EM Width) of the emission signal applied to the each of the pixel areas.

For example, the light-emitting driver may apply, to the second area PA2, a second emission signal with a pulse width less than the pulse width of the first emission signal applied to the first area PA1, and may apply, to the third area PA3, a third emission signal with a pulse width less than the pulse width of the first emission signal.

Referring to FIGS. 13A, 13B , and 13C the data driver 140 may compensate for the luminance difference of the second area PA2 and the third area PA3 by adjusting the offset voltage of the data voltage applied to each of the second area PA2 and the third area PA3 which have luminance values different from that of the first pixel area PA1 because of the curved curvature.

For example, the data driver 140 may apply an offset to the data voltage applied to each of the second area PA2 and the third area PA3 to apply a data voltage (+10 gray) higher than that of the first area PA1 by 10 gray voltage.

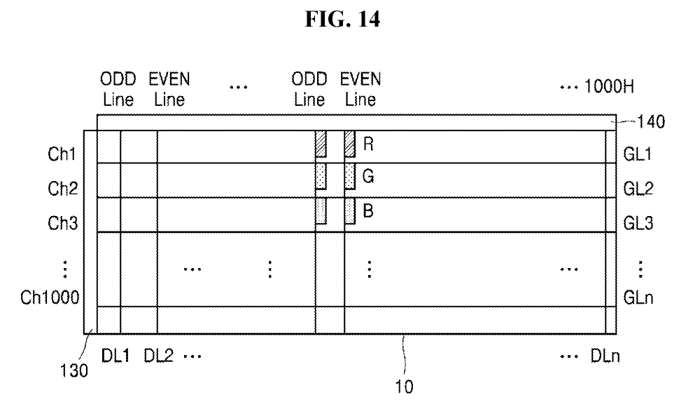

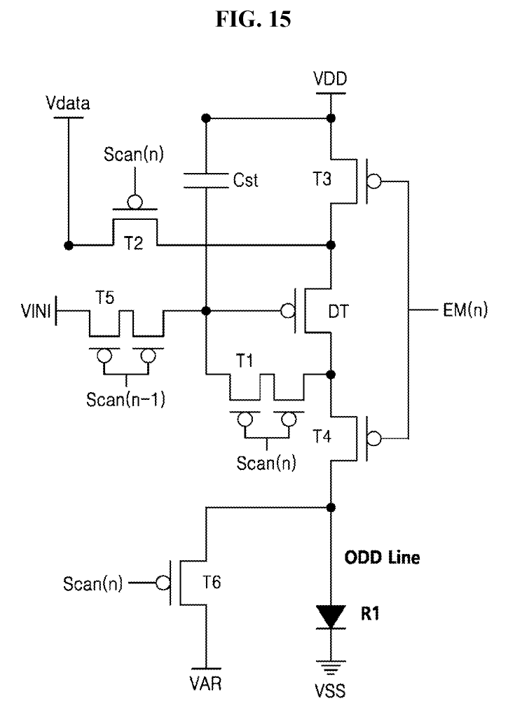

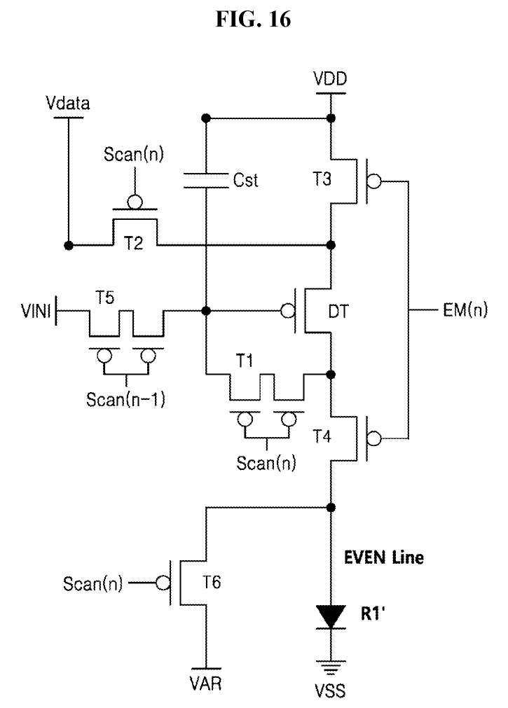

FIG. 14 is a diagram illustrating an example in which odd and even lines are disposed on a display panel according to an embodiment of the invention; FIG. 15 is a diagram illustrating an example in which a sub-pixel is connected to an odd number line according to an embodiment of the invention; and FIG. 16 is a diagram illustrating an example in which a sub-pixel is connected to an even number line according to an embodiment of the invention.

Referring to FIG. 14, in the display panel 10, n data lines DL1 to DLn extending in the vertical direction may be disposed by two at constant intervals in the horizontal direction, wherein an odd number line (ODD Line), which is one of the two, and an even number line (EVEN Line), which is the other one of the two, may be repeatedly disposed. For example, in a case where 1000 data lines DL1 to DL1000 are disposed, the display panel 10 may have 500 odd lines (ODD Line) and 500 even lines (EVEN Line), that is, 1000 data channels 1H to 1000H.

Additionally, in the display panel 10 according to an embodiment of the invention, n gate lines GL1 to GLn extending in a horizontal direction may be disposed at constant intervals in a vertical direction. For example, in a case where 1000 gate lines GL1 to GL1000 are disposed, the display panel 10 may have 1000 scan channels Ch1 to Ch1000.

In this regard, one sub-pixel among red (R), green (G), blue (B) and white (W) sub-pixels may be electrically connected to a point where one gate line GL and one data line DL intersect with each other.

For example, red R, green G, blue B, and white W sub-pixels may be repeated and electrically connected to one odd number line (ODD Line) at respective points where the one odd line intersects the respective gate lines.

Additionally, red R, green G, blue B, and white W sub-pixels may be repeated and electrically connected to the other one even number line (EVEN Line) at respective points where the one odd line intersects the respective gate lines.

Referring to FIG. 15, in the pixel circuit for driving the first-first sub-pixel R1, when the n data lines DL1 to DLn are disposed by two at constant intervals in the horizontal direction, the first-first sub-pixel R1 may be connected to the odd number line (ODD Line), which is one of the two. Here, the first-first sub-pixel R1 is exemplified with a sub-pixel emitting red light, but the inventive concepts are not limited to this. For example, at least one of red R, green G, blue B, and white W sub-pixels may be connected to each odd number line (ODD Line).

Referring to FIG. 16, in the pixel circuit for driving the first-second sub-pixel R1', when the n data lines DL1 to DLn are disposed by two at constant intervals in the horizontal direction, the first-second sub-pixel R1' may be connected to the even number line (EVEN Line), which is one of the two. Here, the first-second sub-pixel R1' is exemplified with a sub-pixel emitting red light, but the inventive concepts are not limited to this. For example, at least one of red R, green G, blue B, and white W sub-pixels may be connected to each even number line (EVEN Line).

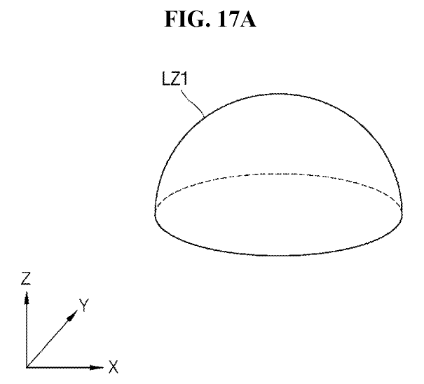

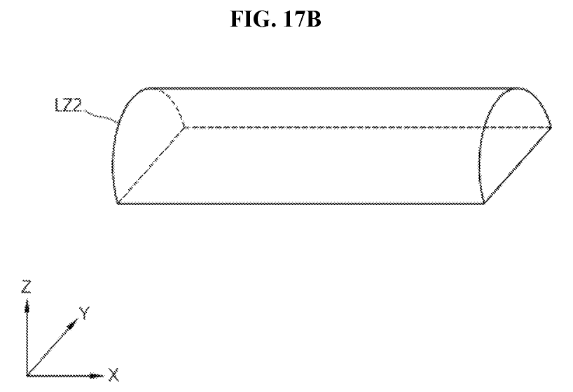

FIG. 17A is a perspective view illustrating a shape structure of a first lens LZ1 according to an embodiment of the invention, and FIG. 17B is a perspective view illustrating a shape structure of a second lens LZ2 according to another embodiment of the invention.

In FIGS. 17A and 17B, a first direction (X) may be expressed as a left-right direction, a lateral direction, a horizontal direction, or an X-axis direction. The second direction Y may be expressed as an up-and-down direction, a longitudinal direction, a vertical direction, or a Y-axis direction. The third direction Z may be expressed as a front-rear direction, a thickness direction of the display panel 10, or a Z-axis direction.

The first lens LZ1 and the second lens LZ2 may differently control (limit) the viewing angle in the left-right direction (X), and equally control (limit) the viewing angle in the up-and-down direction (Y).

For example, the first lens LZ1 may control the viewing angle to be a narrow viewing angle by limiting the traveling path of the light emitted from the light-emitting device to within a specific angle in the left-right direction (X), and the second lens LZ2 may control the viewing angle to be a wide viewing angle by not limiting the traveling path of the light emitted from the light-emitting device to within a specific angle in the left-right direction X.

Referring to FIG. 17A, the first lens LZ1 according to an embodiment of the invention may be a half-spherical lens.

The half-spherical first lens LZ1 may be disposed on the first emission area of the first sub-pixel R1, R1′ in the first pixel area PA1 of FIG. 7 to limit the traveling path of the light generated in the first emission area in the left-right direction, thereby controlling the viewing angle to be a narrow viewing angle. For example, the first lens LZ1 may limit the traveling path of the light emitted through the first emission region from the first-first sub-pixel R1 and the first-second sub-pixel R1' in the left-right direction to control the viewing angle to be a narrow viewing angle, and may limit the same in the up-and-down direction to control the viewing angle to be a narrow viewing angle.

Referring to FIG. 17B, the second lens LZ2 according to another embodiment of the invention may be a half-cylindrical lens elongated in the first direction (X).

The second lens LZ2 may be disposed on the emission region of the light-emitting device in a lens area so that the traveling path of the light generated in the light-emitting area may not be limited in the left-right direction, thereby controlling the viewing angle to be a wide viewing angle. For example, the second lens LZ2 may not limit the traveling path of the light emitted from the second emission region of the second light-emitting device to within a specific angle range in the left-right direction to control the viewing angle to be a wide viewing angle, and may limit the same to within a specific angle range in the up-and-down direction to control the viewing angle to be a narrow viewing angle.

Both the first lens LZ1 and the second lens LZ2 may limit the light traveling path to within a specific angle range in the up-and-down direction (Y) to control the viewing angle to be a narrow viewing angle. Accordingly, in a case where the display device is applied to, for example, an automobile, it is possible to prevent that the image displayed in the first-to-third pixel areas PA1 to PA3 of the display panel 10 is reflected by the windshield of the automobile, obstructing the driver's view.

According to above-described embodiments of the invention, it is possible to realize a display panel in which the first lens is disposed in the first pixel area having no curvature, the second lens is disposed in the second pixel area having the first curvature, the third lens is disposed in the third pixel area having the second curvature, and the second lens and the third lens are disposed to partially overlap respective pixels.

According to embodiments of the invention, it is possible to realize a display device in which a gamma driver applies, to the second pixel area, the second gamma voltage lower than the first gamma voltage applied to the first pixel area, and applies, to the third pixel area, the third gamma voltage lower than the first gamma voltage, in the display panel having the above-described configuration.

According to embodiments of invention, by adding one light-emitting device for each sub-pixel on the curved display panel and changing the corresponding lens configuration, the viewing angle may be effectively improved.

According to embodiments of the invention, by adjusting the diameter or thickness of the lens corresponding to each sub-pixel in the pixel area on the curved display panel, to which the curvature is applied, the luminance difference of the image to which the curvature is applied may be compensated.

According to embodiments of the invention, by changing the configuration of the lens corresponding to each sub-pixel in the pixel area in the curved display panel, to which the curvature is applied, the direction of light emitted from each light-emitting device may be controlled to a wide-angle area or a narrow-angle area, thereby adjusting the viewer's viewing angle.

According to embodiments of the invention, it is possible to improve optical efficiency because there is no optical loss owing to the absence of additional layers.

According to embodiments of the invention, it is possible to improve the lifespan of a display device by compensating for the luminance difference of a curved display panel.

According to embodiments of the invention, by compensating for the luminance difference of the curved display panel, the viewer's viewing angle may be improved, and the lifespan of the display device product may be extended.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display panel comprising:
a first pixel area;
a second pixel area disposed on a first side of the first pixel area;
a third pixel area disposed on a second side of the first pixel area and facing the second pixel area with the first pixel area interposed therebetween;
a plurality of first sub-pixels disposed in the first pixel area;
a plurality of second sub-pixels disposed in the second pixel area;
a plurality of third sub-pixels disposed in the third pixel area;
a plurality of first lenses disposed to correspond to the plurality of first sub-pixels, respectively;
a plurality of second lenses disposed to correspond to the plurality of second sub-pixels, respectively; and
a plurality of third lenses disposed to correspond to the plurality of third sub-pixels, respectively,
wherein:
the second pixel area is curved toward a rear surface of the display panel and has a first curvature;
the third pixel area is curved toward the rear surface of the display panel and has a second curvature;
the plurality of first sub-pixels overlap the plurality of first lenses, respectively; and
the plurality of second lenses and third lenses partially overlap with the plurality of second sub-pixels and third sub-pixels, respectively.

2. The display panel of claim 1, wherein:
one of the plurality of second sub-pixels entirely overlaps with the second lens as a whole, and another one of the plurality of second sub-pixels only partially overlaps with the second lens; and
one of the plurality of third sub-pixels overlaps with the third lens as a whole, and another one of the plurality of second sub-pixels only partially overlaps with the third lens.

3. The display panel of claim 2, wherein:
in the first pixel area, the plurality of first sub-pixels overlap with the plurality of first lenses, respectively, so that each of the plurality of first sub-pixels is entirely covered by each of the plurality of first lenses;
in the second pixel area, one of the plurality of second sub-pixels overlaps with one second lens so as to be entirely covered by the one second lens, and another one of the plurality of second sub-pixels partially overlaps with another second lens so as to be partially covered by the another second lens; and
in the third pixel area, one of the plurality of third sub-pixels overlaps with one third lens so as to be entirely covered by the one third lens, and another one of the plurality of third sub-pixels partially overlaps with another third lens so as to be partially covered by the another third lens.

4. The display panel of claim 3, wherein:
the plurality of second sub-pixels include a second-first sub-pixel disposed toward a one-side outer peripheral portion and a second-second sub-pixel disposed toward the first pixel area;
the plurality of third sub-pixels include a third-first sub-pixel disposed toward another-side outer peripheral portion and a third-second sub-pixel disposed toward the first pixel area;
the plurality of second lenses include a second-first lens overlapping with the second-first sub-pixel and a second-second lens partially overlapping with the second-second sub-pixel; and
the plurality of third lenses include a third-first lens overlapping with the third-first sub-pixel and a third-second lens partially overlapping with the third-second sub-pixel.

5. The display panel of claim 4, wherein:
the second-second lens is disposed to be shifted by a first predetermined distance in a direction from the second-second sub-pixel to the first pixel area; and
the third-second lens is disposed to be shifted by a second predetermined distance in a direction from the third-second sub-pixel to the first pixel area.

6. The display panel of claim 5, wherein each of the plurality of first sub-pixels, second sub-pixels, and third sub-pixels has a same size, area, and thickness.

7. The display panel of claim 6, wherein each of the plurality of first lenses, second lenses, and third lenses has a same shape, diameter, thickness, and length.

8. The display panel of claim 6, wherein each of the plurality of first lenses, second lenses, and third lenses has a same shape, and has different diameters, thicknesses, and lengths from each other.

9. The display panel of claim 7, wherein:
the first pixel area is in a flat state without being curved or bent in a front surface direction that is a direction in which light is emitted from each sub-pixel;
the second pixel area is curved toward the rear surface of the display panel with the first curvature; and
the third pixel area is curved toward the rear surface of the display panel with the second curvature to be symmetrical to the second pixel area in a transverse direction with respect to the first pixel area.

10. The display panel of claim 9, wherein a value of the first curvature and a value of the second curvature are substantially the same.

11. The display panel of claim 9, wherein a value of the first curvature and a value of the second curvature are different from each other.

12. The display panel of claim 10, wherein:
the first pixel area is disposed at a center of the display panel;
the second pixel area is disposed on a first side of the first pixel area, and
the third pixel area is disposed on a second side of the first pixel area so as to face the second pixel area, with the first pixel area interposed therebetween.

13. The display panel of claim 8, wherein, in a case where the second lens and the third lens are of a half-spherical type, each of the diameter, thickness, and length of the second-second lens is greater than each of the diameter, thickness, and length of the second-first lens, respectively, and each of the diameter, thickness, and length of the third-second lens is greater than each of the diameter, thickness, and length of the third-first lens, respectively.

14. The display panel of claim 1, wherein:
the first pixel area, the second pixel area, and the third pixel area include:
a first insulating layer, the plurality of first, second, and third sub-pixels being disposed on the first insulating layer;
a second insulating layer disposed on the plurality of first, second, and third sub-pixels;
a black matrix partially opened on the second insulating layer; and
a third insulating layer disposed on the black matrix, the plurality of first, second, and third lenses being disposed on the third insulating layer;
the black matrix includes a plurality of first openings opened to respectively correspond to the plurality of first sub-pixels, a plurality of second openings opened to respectively correspond to the plurality of second sub-pixels, and a plurality of third openings opened to respectively correspond to the plurality of third sub-pixels;
in the second pixel area, one of the plurality of second sub-pixels overlaps with one of the plurality of second openings, and another one of the plurality of second sub-pixels partially overlaps with the other of the plurality of second openings; and
in the third pixel area, one of the plurality of third sub-pixels overlaps with one of the plurality of third openings, and another one of the plurality of third sub-pixels partially overlaps with another one of the plurality of third openings.

15. A display device comprising:
a display panel including:
a first pixel area;
a second pixel area disposed on a first side of the first pixel area;
a third pixel area disposed on a second side of the first pixel area, which faces the second pixel area with respect to the first pixel area;
a plurality of first sub-pixels disposed in the first pixel area;
a plurality of second sub-pixels disposed in the second pixel area;
a plurality of third sub-pixels disposed in the third pixel area;
a plurality of first lenses disposed to correspond to the plurality of first sub-pixels, respectively;
a plurality of second lenses disposed to correspond to the plurality of second sub-pixels, respectively; and
a plurality of third lenses disposed to correspond to the plurality of third sub-pixels, respectively;
a data driver configured to apply a data voltage to the display panel;
a gamma driver configured to apply a gamma voltage to the display panel;
a gate driver configured to apply a gate voltage to the display panel; and
a controller configured to control the data driver and the gate driver,
wherein:
the plurality of first sub-pixels overlap the plurality of first lenses, respectively;
one of the plurality of second sub-pixels entirely overlaps with one of the second lenses, and another one of the plurality of second sub-pixels partially overlaps with the other of the second lenses;
one of the plurality of third sub-pixels entirely overlaps with one of the third lenses, and another one of the plurality of third sub-pixels partially overlaps with the other one of the third lenses; and
the gamma driver is configured to apply, to the second pixel area, a second gamma voltage lower than a first gamma voltage applied to the first pixel area, and to apply, to the third pixel area, a third gamma voltage lower than the first gamma voltage.

16. The display device of claim 15, wherein:
the gamma driver applies, to each of the first pixel area, the second pixel area, and the third pixel area, a gamma reference high voltage having a same voltage level; and
the gamma driver applies, to the second pixel area and the third pixel area, second and third gamma reference low voltages lower than a first gamma reference low voltage applied to the first pixel area, respectively.

17. The display device of claim 16, wherein:
the gate driver includes a scan driver configured to apply a scan signal to the display panel, and a light-emitting driver configured to apply an emission signal to the display panel; and
the light-emitting driver applies, to the second pixel area, a second emission signal with a pulse width less than a pulse width of a first emission signal applied to the first pixel area, and applies, to the third pixel area, a third emission signal with a pulse width less than the pulse width of the first emission signal.

18. The display device of claim 17, wherein the data driver applies an offset to data voltage applied to each of the second pixel area and the third pixel area to apply a data voltage higher than that of the first pixel area by 10 gray voltage.

19. The display panel of claim 18, wherein:
an odd number line and an even number line extending in a vertical direction are disposed in each of the first pixel area, the second pixel area, and the third pixel area;
one of the plurality of first sub-pixels is connected to the odd number line or the even number line, and another one of the plurality of first sub-pixels is connected to the even number line or the odd number line, respectively;
one of the plurality of second sub-pixels is connected to the odd number line or the even number line, and another one of the plurality of second sub-pixels is connected to the even number line or the odd number line, respectively; and
one of the plurality of third sub-pixels is connected to the odd number line or the even number line, and another one of the plurality of third sub-pixels is connected to the even number line or the odd number line, respectively.

20. A display panel comprising:
a first pixel area;
a second pixel area disposed on a first side of the first pixel area;
a third pixel area disposed on a second side of the first pixel area;
a plurality of first sub-pixels disposed in the first pixel area;
a plurality of second sub-pixels disposed in the second pixel area;
a plurality of third sub-pixels disposed in the third pixel area;
a plurality of first lenses disposed to correspond to the plurality of first sub-pixels, respectively;
a plurality of second lenses disposed to correspond to the plurality of second sub-pixels, respectively; and
a plurality of third lenses disposed to correspond to the plurality of third sub-pixels, respectively,
wherein:
the second pixel area is bendable toward a rear surface of the display panel;
the third pixel area is bendable toward the rear surface of the display panel; and
when viewed in plan, at least one of the plurality of second sub-pixels is partially exposed from a corresponding one of the plurality of second lenses, while the remaining second sub-pixels are entirely covered by their corresponding second lenses.
